(19) United States
(12) Patent Application Publication
(10) Pub. No.: US 2006/0202041 A1
(43) Pub. Date: Sep. 14, 2006

(54) Integrated circuit card and a method for manufacturing the same

(75) Inventors: Hirotaka Hishizawa, Fuchu (JP); Kenji Osawa, Hachioji (JP); Junichiro Osako, Kodaira (JP); Tamaki Wada, Higashimurayama (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/368,454

(22) Filed: Mar. 7, 2006

(30) Foreign Application Priority Data
Mar. 14, 2005 (JP) 2005-070640

(51) Int. Cl. G06K 19/06; H01L 23/02

(52) U.S. Cl. 235/492; 257/679

(57) ABSTRACT

A semiconductor chip is mounted onto a wiring substrate having external connecting terminals, electrodes on the semiconductor chip and wiring lines on the wiring substrate are connected together electrically through bonding wires, and a sealing portion is formed by resin molding, to form an IC body. Further, a case formed of a thermoplastic resin is provided. The IC body is mounted into a recess of the case through a bonding material. Thereafter, a region near the recess of the case is deformed plastically to fix the IC body to the case and then the bonding material is cured. In this way there is fabricated an IC card comprising the case and the IC body whose stability is improved by being bonded to the case through the bonding material. The production yield of the IC card can be improved.

### CROSS-REFERENCE TO RELATED APPLICATION

The present application claims priority from Japanese patent application No. 2005-070640 filed on Mar. 14, 2005, the content of which is hereby incorporated by reference into this application.

### BACKGROUND OF THE INVENION

The present invention relates to an IC (Integrated Circuit) card manufacturing technique and an IC card, and more particularly to a technique applicable effectively to, for example, a semiconductor memory card (hereinafter referred to simply as “memory card”) and a technique for manufacturing the same.

Among various IC cards which are in use, semiconductor memory cards (simply as “memory cards” hereinafter) such as a multi-media card (there is a standard established by Multi-Media Card Association) and an SD memory card (there is a standard established by SD Card Association) are a kind of a storage device which stores information in a semiconductor memory chip mounted therein. According to this storage device, for write and read of information, access is made directly or electrically to a non-volatile memory formed in the semiconductor memory chip, and the storage device has an excellent characteristic such that there is no mechanical control and that the replacement of a storage medium is easy. Besides, since the storage device is small-sized and light-weight, it is used mainly as an auxiliary storage device in a device for which portability is required such as, for example, a portable personal computer, a portable telephone or a digital camera.

In Japanese Unexamined Patent Publication No. 2004-126654 (Patent Literature 1) there is described a technique on a memory card of the type in which a memory body having a wiring substrate and a semiconductor chip mounted on a main surface of the wiring substrate is held in a sandwiched fashion by both first and second cases.

[Patent Literature 1]

Japanese Unexamined Patent Publication No. 2004-126654

### SUMMARY OF THE INVENTION

Studies made by the present inventors have revealed the following facts.

An IC card can be formed by bonding and uniting two members which are a semiconductor device and a case which carries the semiconductor device thereon, the semiconductor device comprising a wiring substrate and a semiconductor chip mounted and molded thereon. The case can be formed, for example, by an injection molding method using a thermosetting resin material and thus the case can be formed relatively inexpensively. On the other hand, the semiconductor device formed by mounting and molding a semiconductor chip on a wiring substrate is apt to be high in its manufacturing cost, but by making the size of the semiconductor device smaller than that of the IC card, it is possible to increase the number of semiconductor devices capable of being produced from a single wiring substrate and hence possible to decrease the semiconductor device manufacturing cost. By bonding the semiconductor device in question to an inexpensive case larger than the semiconductor device and which substantially defines the outline of the IC card to form the same card, it is possible to reduce the IC card manufacturing cost.

In case of bonding two members (the semiconductor device and the case) to form the IC card, the thickness of the IC card thus formed is required to have high accuracy. If the IC card is thicker than its standard value, then at the time of inserting or pulling out the IC card into or from a slot, there is a possibility that a coating such as Au plating formed on an electrode surface within the slot may be damaged. If the IC card is thinner than its standard value, then at the time of inserting the IC card into the slot, there may occur a contact imperfection between an external connecting terminal in the IC card and an electrode formed in the slot. Therefore, it is desired to fabricate the IC card so that the thickness thereof is in accurate conformity with its standard value.

However, since it takes times for a bonding material to cure, if the semiconductor device moves from the case during curing (before completion of the curing) of the bonding material after the semiconductor device is mounted on the case through the bonding material, there is a possibility that the final IC card thickness after curing of the bonding material may become deviated from its standard value. It is necessary that the IC card deviated from its standard value of thickness be sorted as a defective card and removed. This leads to a lowering of the IC card production yield.

Further, in case of forming the IC card by bonding two members (the semiconductor device and the case) with use of a bonding material, if the bonding material adheres to an outer surface of the IC card, especially to external terminals of the IC card, there is a possibility that the connection reliability of the IC card fabricated may be deteriorated. Therefore, it is necessary that the IC card with the bonding material adhered to the outer surface be sorted as a defective card and removed. This causes the IC card production yield to be deteriorated.

These problems are becoming more and more serious with the reduction in size of IC card.

It is an object of the present invention to provide a technique able to improve the IC card production yield.

The above and other objects and novel features of the present invention will become apparent from the following description and the accompanying drawings.

The following is an outline of typical modes of the present invention as disclosed herein.

According to the present invention, a semiconductor device comprising a wiring substrate and a semiconductor chip mounted thereon is mounted on a case through a bonding material, a part of the case is deformed and the semiconductor device is fixed to the case, then the bonding material is cured to form an IC card.

According to the present invention, in case of mounting a semiconductor device comprising a wiring substrate and a semiconductor chip mounted thereon into a recess of a case through a bonding material and then curing the bonding material to form an IC card, a protuberance is formed on a bottom of the recess of the case or on a surface of the semiconductor device opposed to the bottom.

According to the present invention, in case of mounting a semiconductor device comprising a wiring substrate and a semiconductor chip mounted thereon into a recess of a case through a bonding material and then curing the bonding material to form an IC card, a protuberance is formed on a side wall of the recess of the case so that the semiconductor device is fixed by the protuberance when mounted into the recess of the case.

According to the present invention, a semiconductor device comprising a wiring substrate and a semiconductor chip mounted thereon is bonded (mounted) to a recess of a case through a bonding material and a part of the case extends onto the semiconductor device.

According to the present invention, a semiconductor device comprising a wiring substrate and a semiconductor chip mounted thereon is bonded (mounted) to a recess of a case through a bonding material and a protuberance is formed on a bottom of the recess of the case or on a surface of the semiconductor device opposed to the bottom.

According to the present invention, a semiconductor device comprising a wiring substrate and a semiconductor chip mounted thereon is mounted on a metallic material portion of a case having both a resin material portion and the metallic material portion, and a part of the metallic material portion of the case extends onto the semiconductor device.

According to the present invention, a semiconductor device comprising a wiring substrate and a semiconductor chip mounted thereon is bonded (mounted) to a recess of a case through a bonding material, and a protuberance is formed on a side wall of the recess of the case.

As an effect obtained by the typical modes of the present invention as disclosed herein, the production yield of the semiconductor device can be improved.

### BRIEF DESCRIPTION OF THE DRAWIGNS

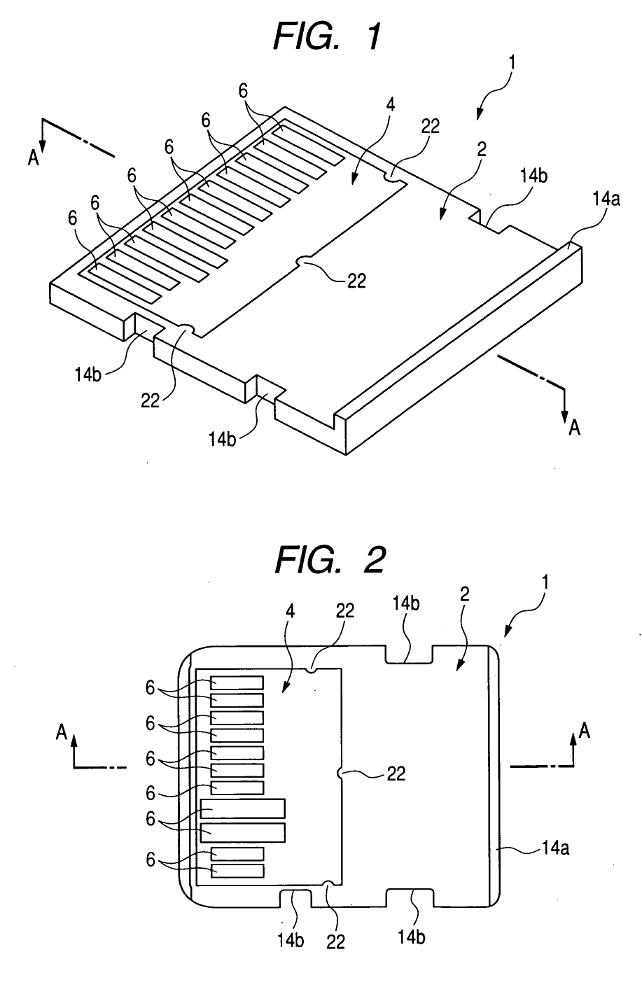

FIG. 1 is a perspective view of an IC card according to a first embodiment of the present invention;

FIG. 2 is a back view of the IC card of FIG. 1;

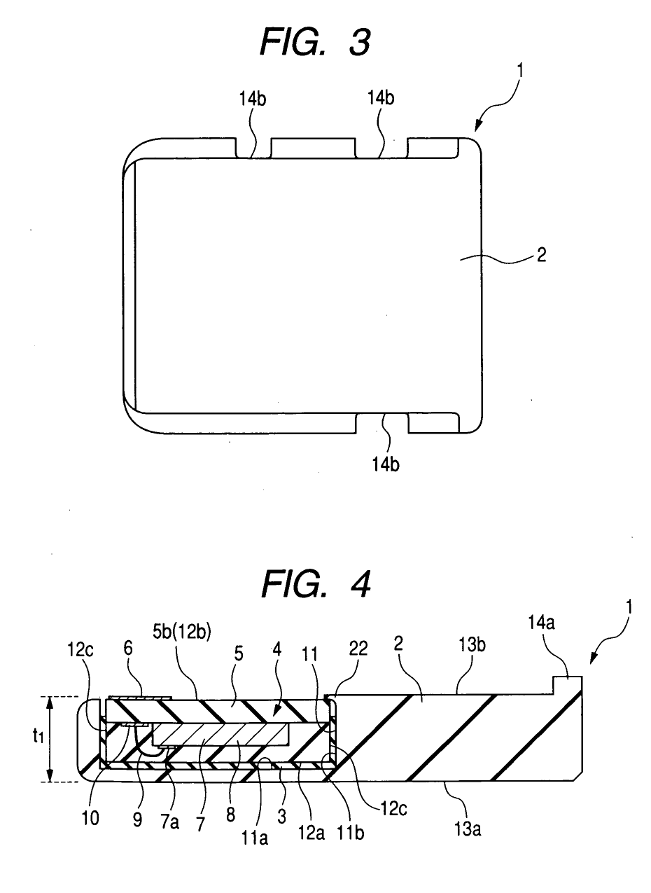

FIG. 3 is a top view of the IC card of FIG. 1;

FIG. 4 is a sectional view of the IC card of FIG. 1;

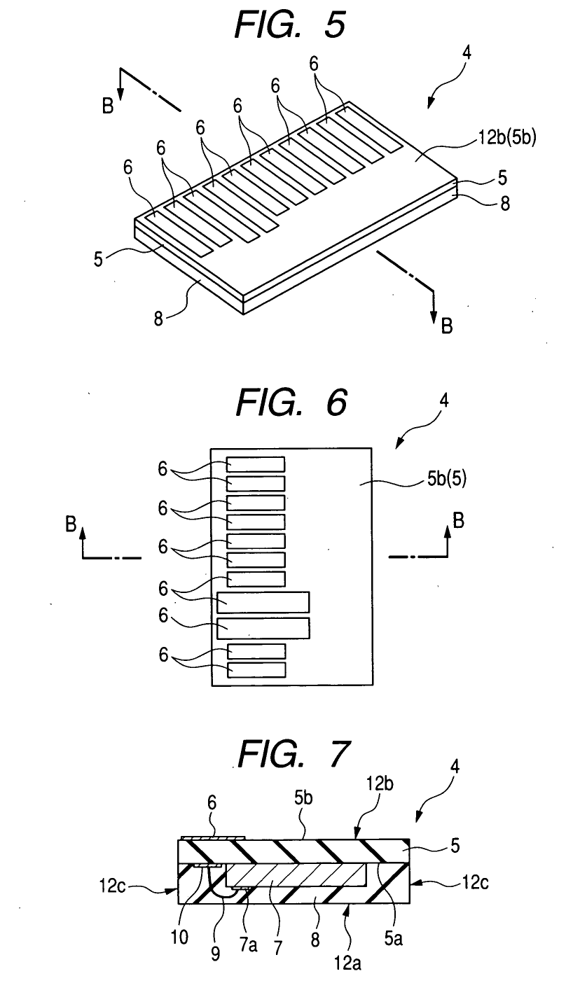

FIG. 5 is a perspective view showing an appearance of an IC body used in the IC card of FIG. 1;

FIG. 6 is a back view of the IC body of FIG. 5;

FIG. 7 is a sectional view of the IC body of FIG. 5;

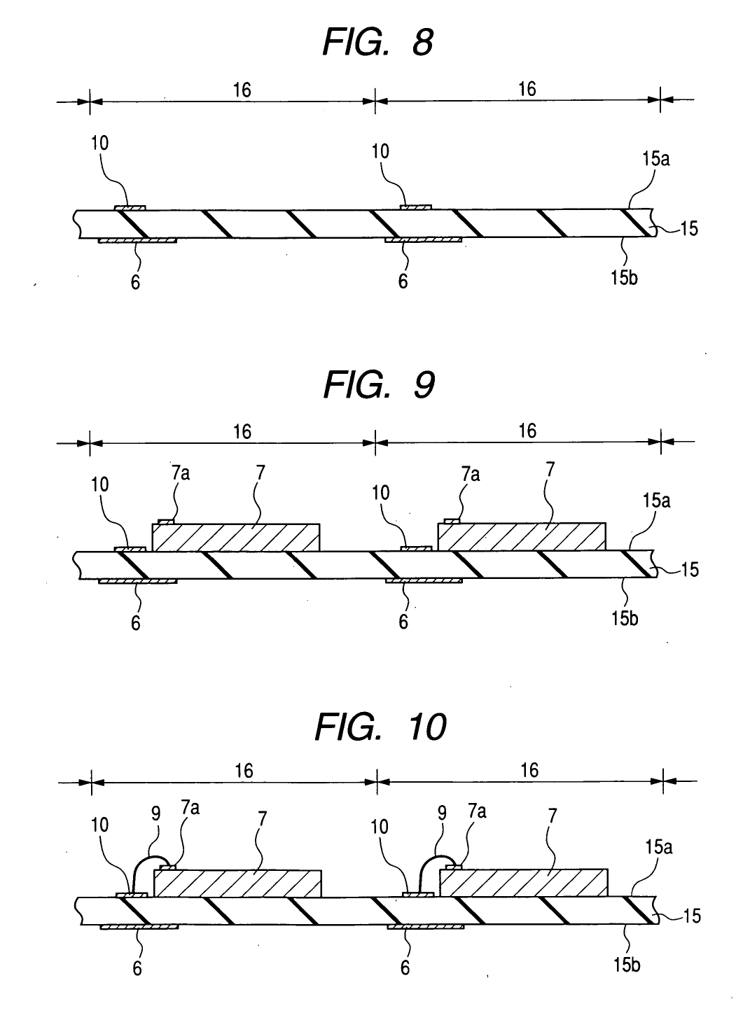

FIG. 8 is a sectional view of the IC body of FIG. 5 in a manufacturing step;

FIG. 9 is a sectional view of the IC body in a manufacturing step which follows FIG. 8;

FIG. 10 is a sectional view of the IC body in a manufacturing step which follows FIG. 9;

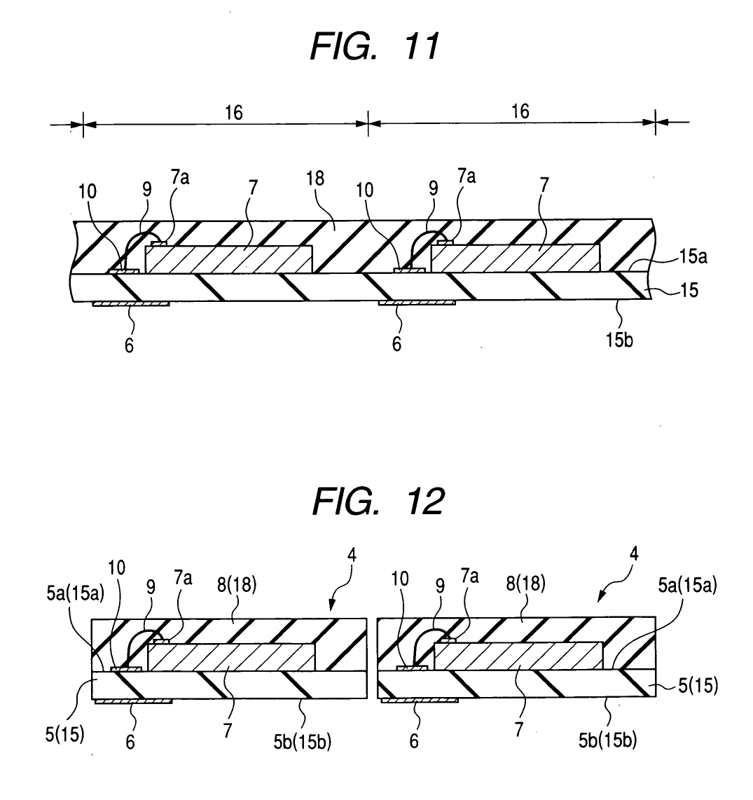

FIG. 11 is a sectional view of the IC body in a manufacturing step which follows FIG. 10;

FIG. 12 is a sectional view of the IC body in a manufacturing step which follows FIG. 11;

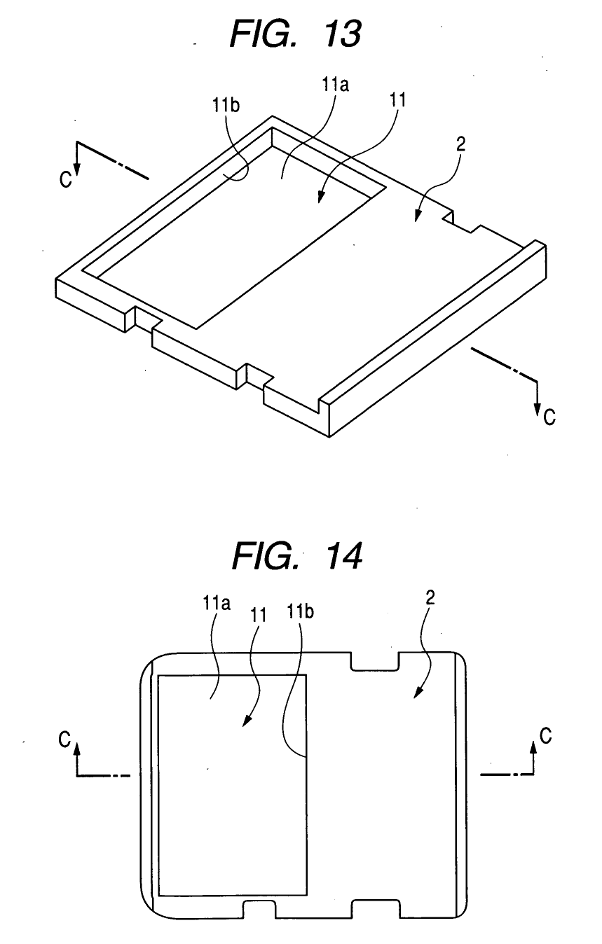

FIG. 13 is a perspective view showing an appearance of a case used in manufacturing the IC card of FIG. 1;

FIG. 14 is a back view of the case of FIG. 13;

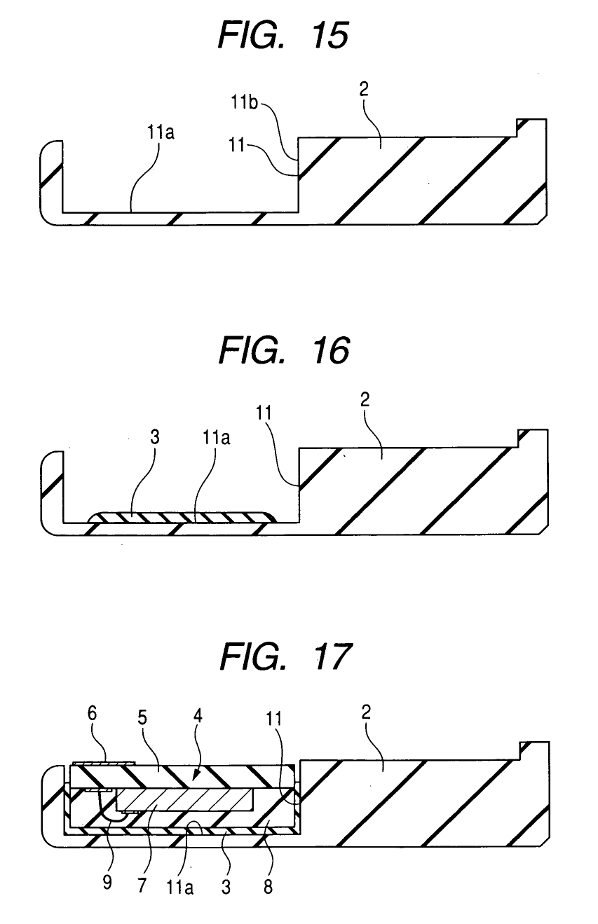

FIG. 15 is a sectional view of the case of FIG. 13;

FIG. 16 is a sectional view of the IC card of FIG. 1 in a manufacturing step;

FIG. 17 is a sectional view of the IC card in a manufacturing step which follows FIG. 16;

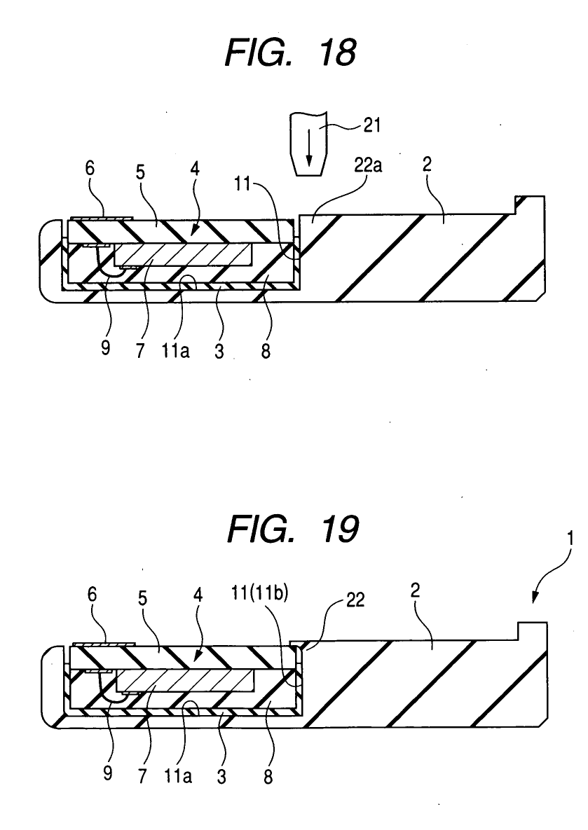

FIG. 18 is a sectional view of the IC card in a manufacturing step which follows FIG. 17;

FIG. 19 is a sectional view of the IC card in a manufacturing step which follows FIG. 18;

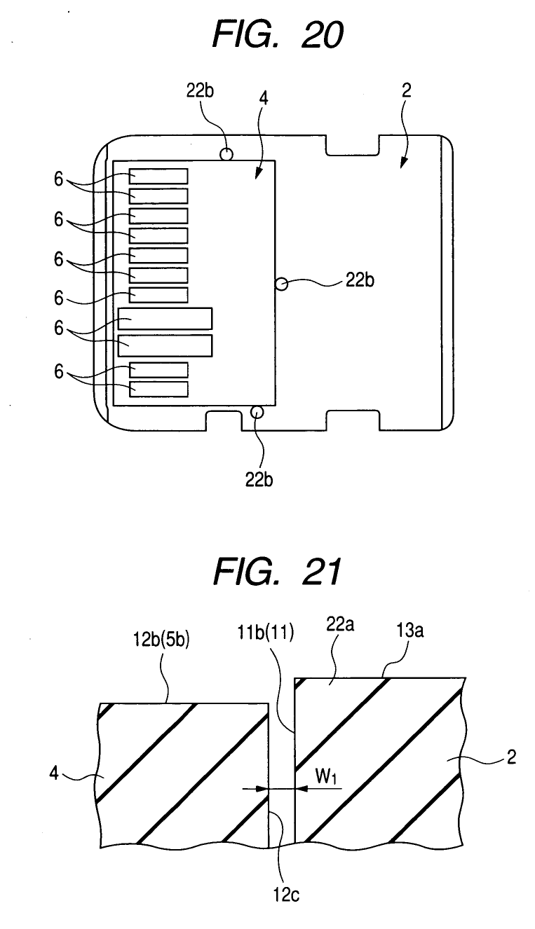

FIG. 20 is a plan view showing an area where the case is to be deformed by pushing a tool thereagainst;

FIG. 21 is an explanatory diagram showing in what manner the case is deformed by the tool;

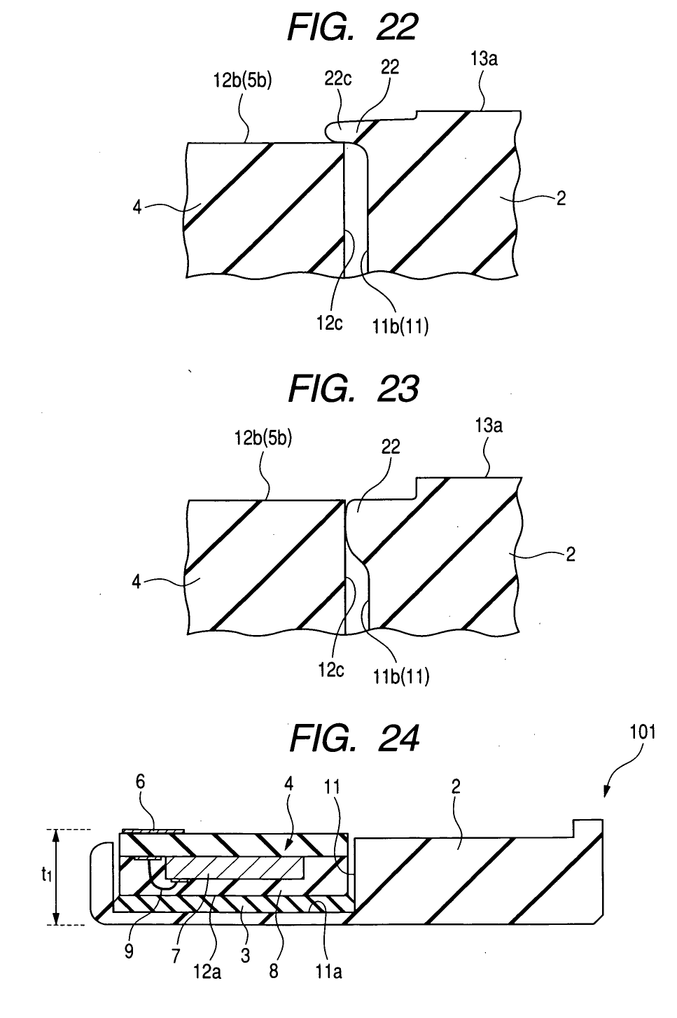

FIG. 22 is an explanatory diagram showing in what manner the case is deformed by the tool;

FIG. 23 is an explanatory diagram showing in what manner the case is deformed by the tool;

FIG. 24 is a sectional view of an IC card as a comparative example;

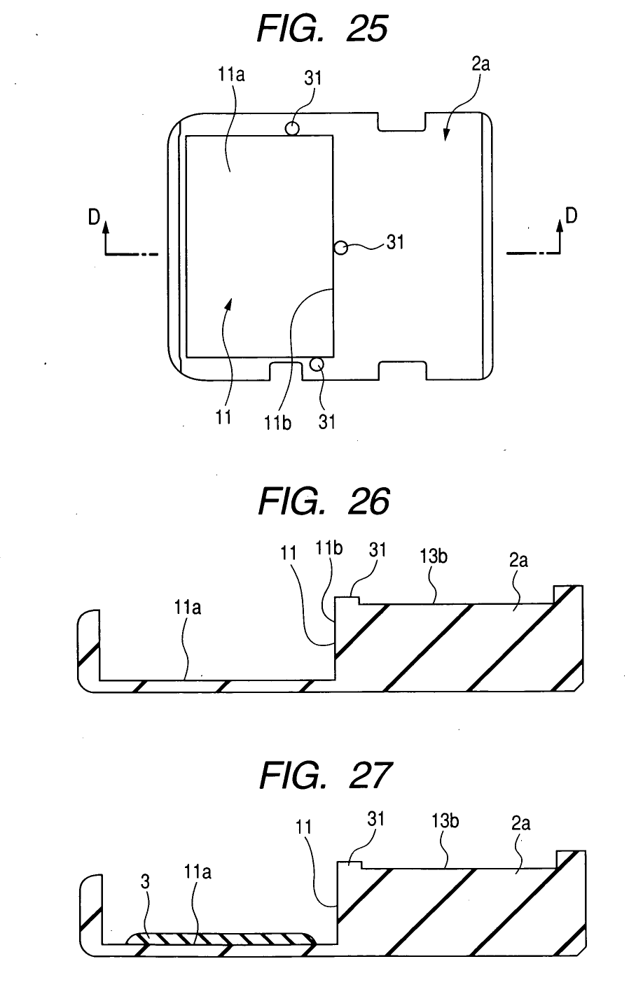

FIG. 25 is a back view of a case used in manufacturing an IC card according to a second embodiment of the present invention;

FIG. 26 is a sectional view of the case of FIG. 25;

FIG. 27 is a sectional view of the IC card of the second embodiment in a manufacturing step;

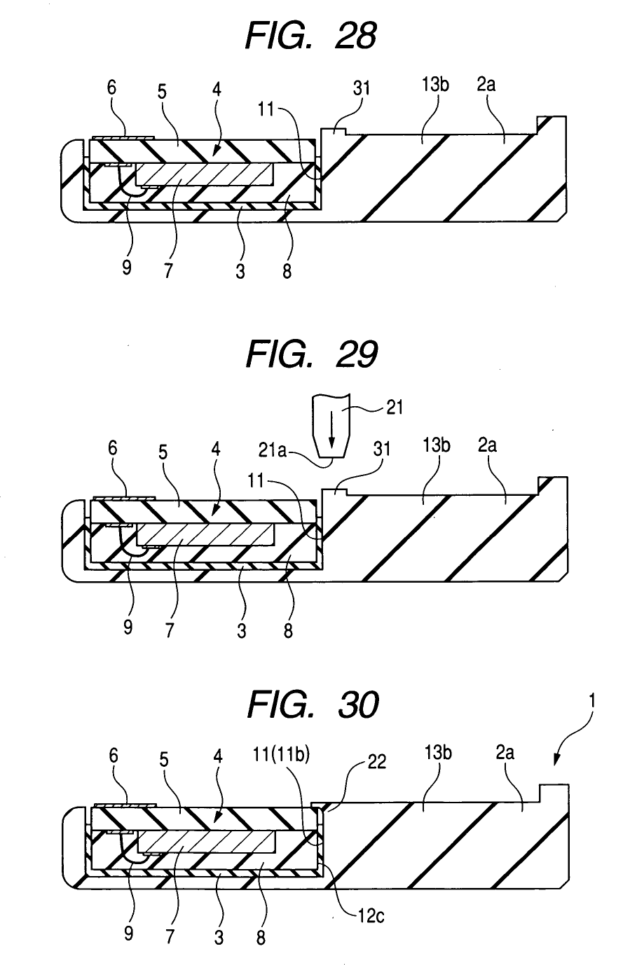

FIG. 28 is a sectional view of the IC card in a manufacturing step which follows FIG. 27;

FIG. 29 is a sectional view of the IC card in a manufacturing step which follows FIG. 28;

FIG. 30 is a sectional view of the IC card in a manufacturing step which follows FIG. 29;

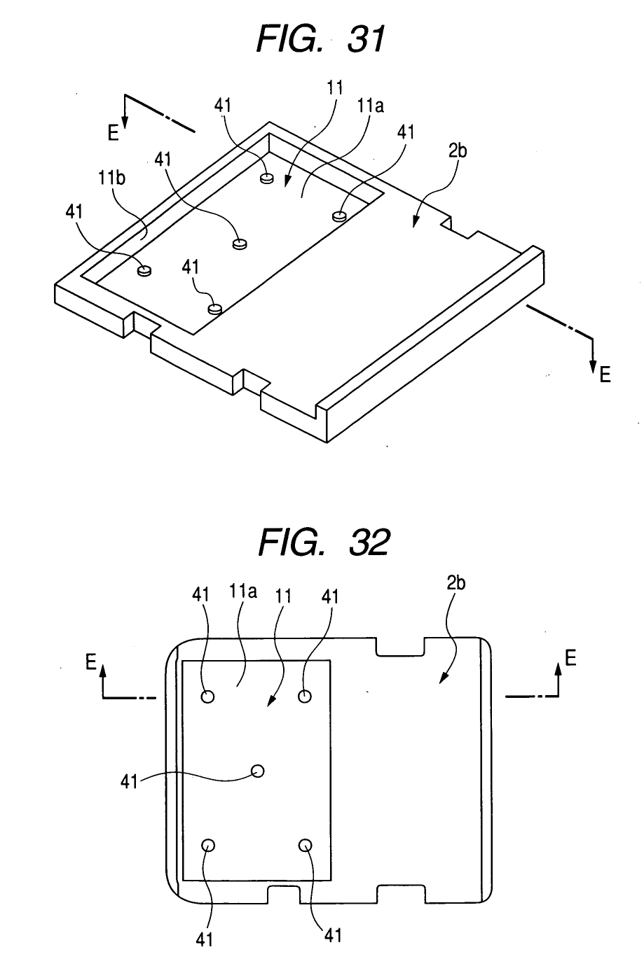

FIG. 31 is a perspective view showing an appearance of a case used in manufacturing an IC card according to a third embodiment of the present invention;

FIG. 32 is a back view of the case of FIG. 31;

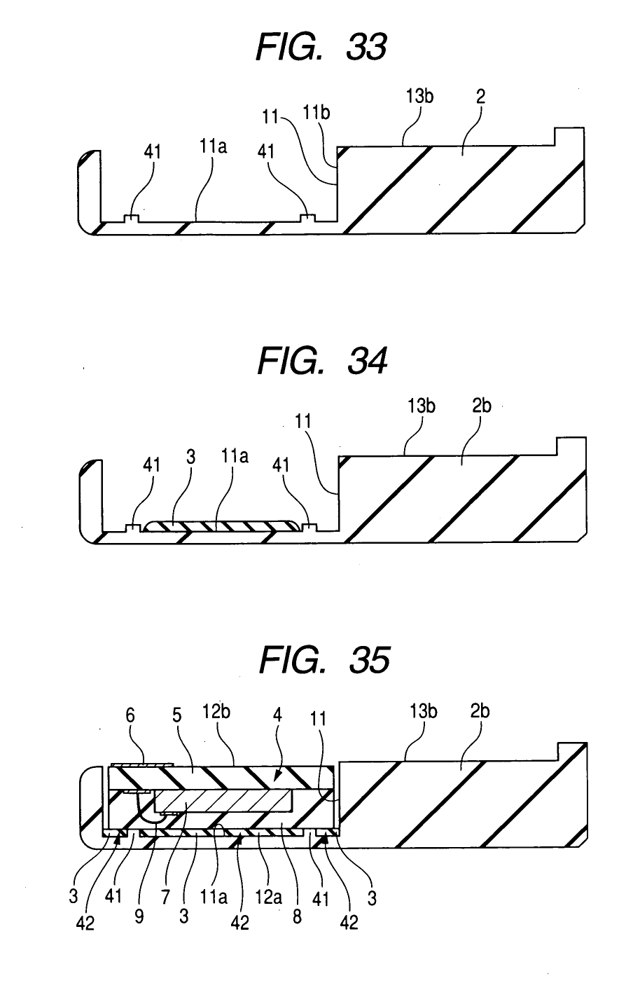

FIG. 33 is a sectional view of the case of FIG. 31;

FIG. 34 is a sectional view of an IC card of the third embodiment in a manufacturing step;

FIG. 35 is a sectional view of the IC card in a manufacturing step which follows FIG. 34;

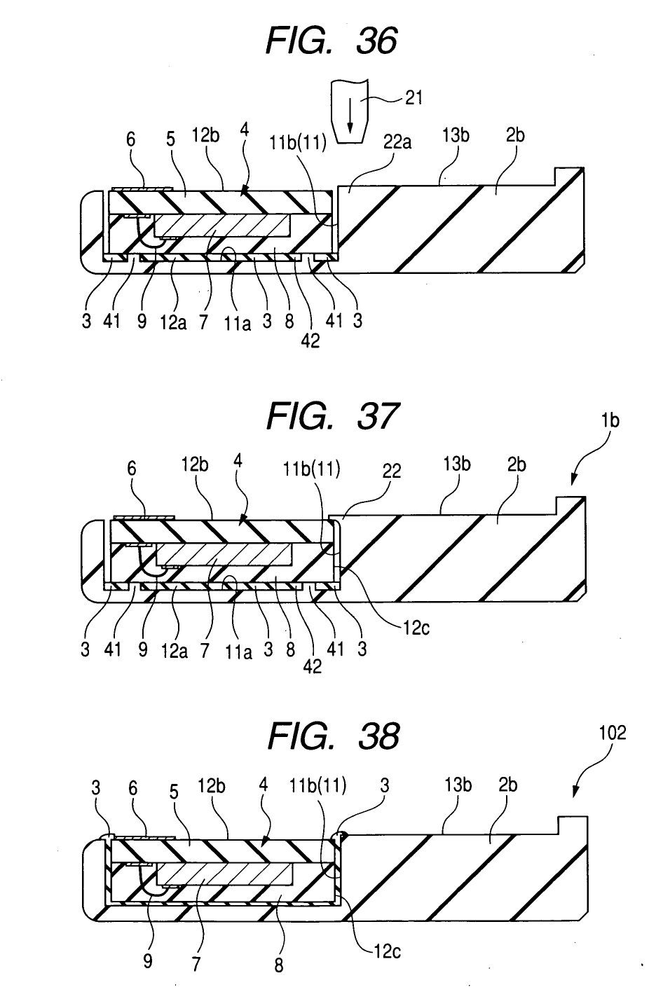

FIG. 36 is a sectional view of the IC card in a manufacturing step which follows FIG. 35;

FIG. 37 is a sectional view of the IC card in a manufacturing step which follows FIG. 36;

FIG. 38 is a sectional view of an IC card as another comparative example;

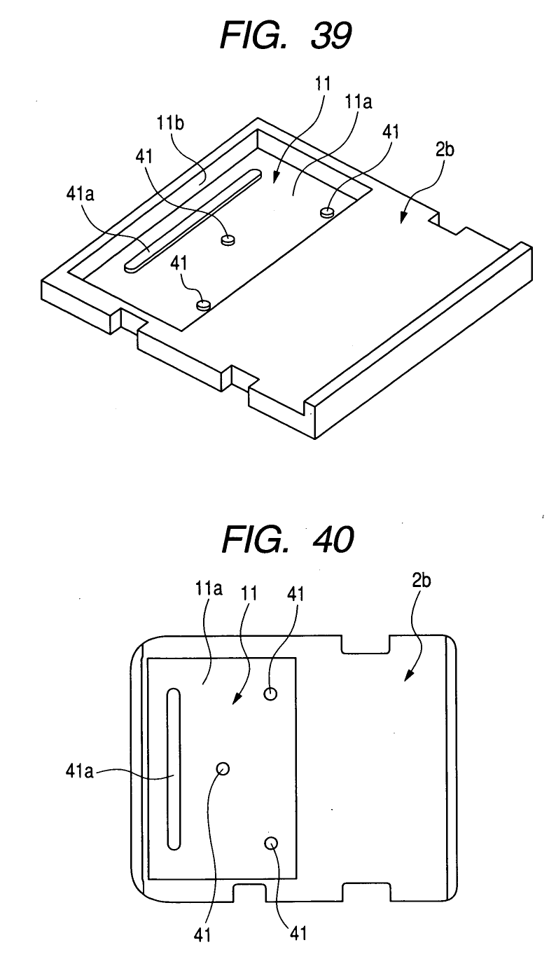

FIG. 39 is a perspective view of a case of another form used in manufacturing the IC card of the third embodiment;

FIG. 40 is a back view of the case of FIG. 39;

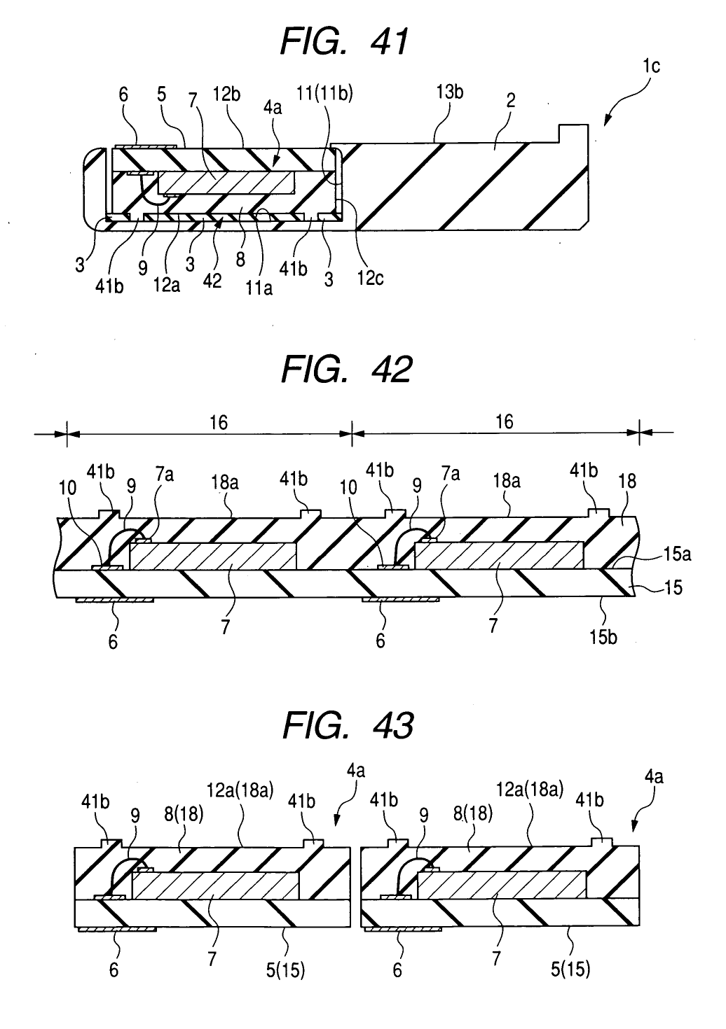

FIG. 41 is a sectional view of an IC card according to a fourth embodiment of the present invention;

FIG. 42 is a sectional view in a manufacturing step of an IC body used in the IC card of FIG. 41;

FIG. 43 is a sectional view of the IC body in a manufacturing step which follows FIG. 42;

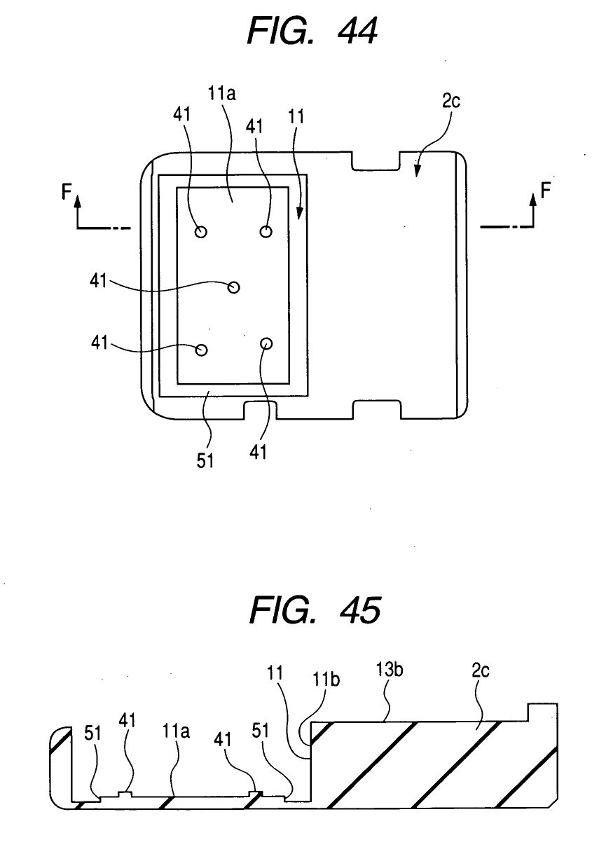

FIG. 44 is a back view showing a case used in manufacturing an IC card according to a fifth embodiment of the present invention;

FIG. 45 is a sectional view of the case of FIG. 44;

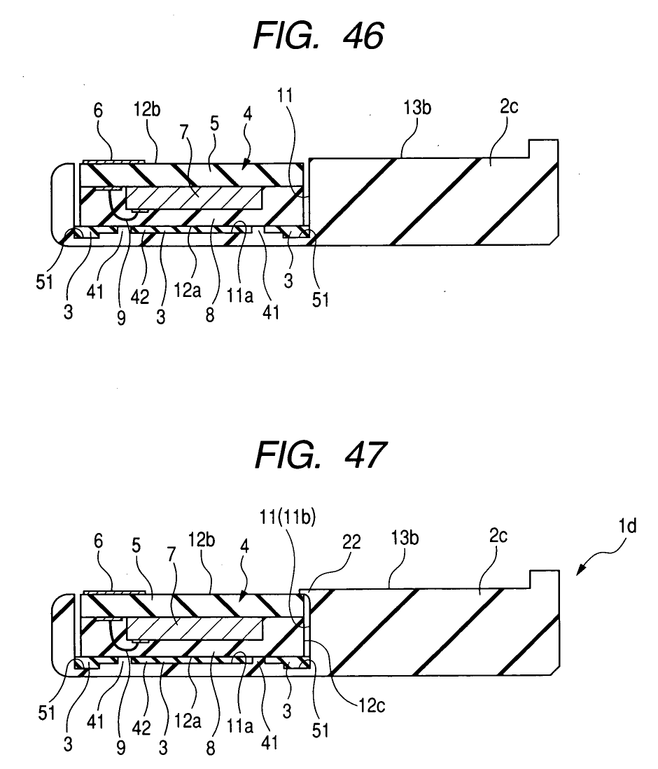

FIG. 46 is a sectional view of the IC card of the fifth embodiment in a manufacturing step;

FIG. 47 is a sectional view of the IC card in a manufacturing step which follows FIG. 46;

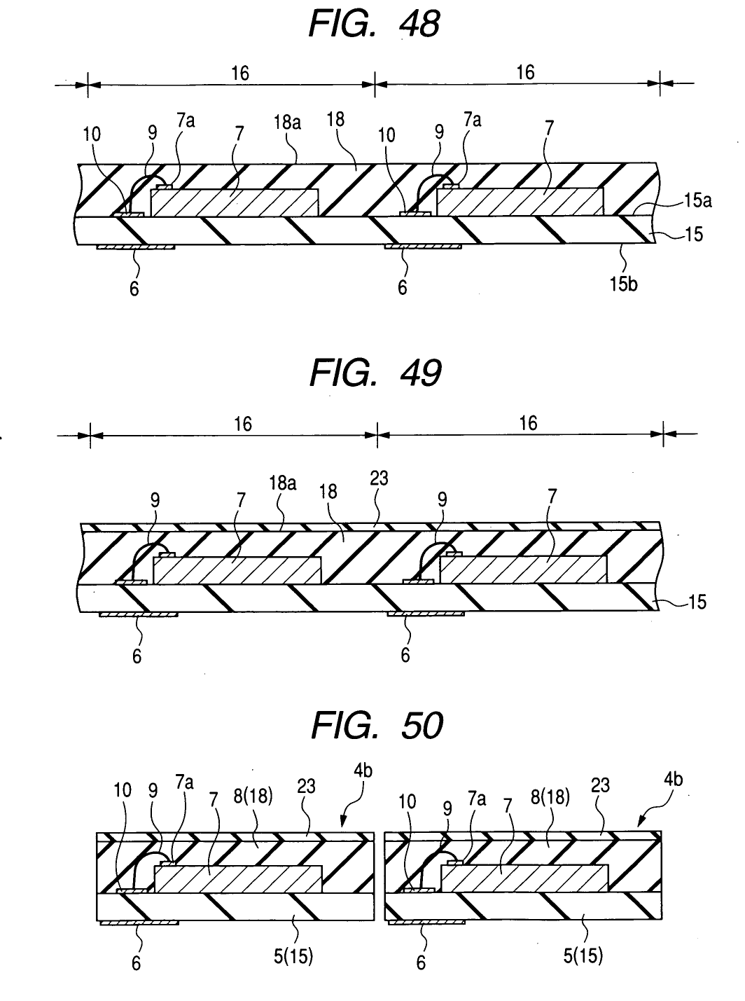

FIG. 48 is a sectional view in a manufacturing step of an IC body used in an IC card according to a sixth embodiment of the present invention;

FIG. 49 is a sectional view of the IC body in a manufacturing step which follows FIG. 48;

FIG. 50 is a sectional view of the IC body in a manufacturing step which follows FIG. 49;

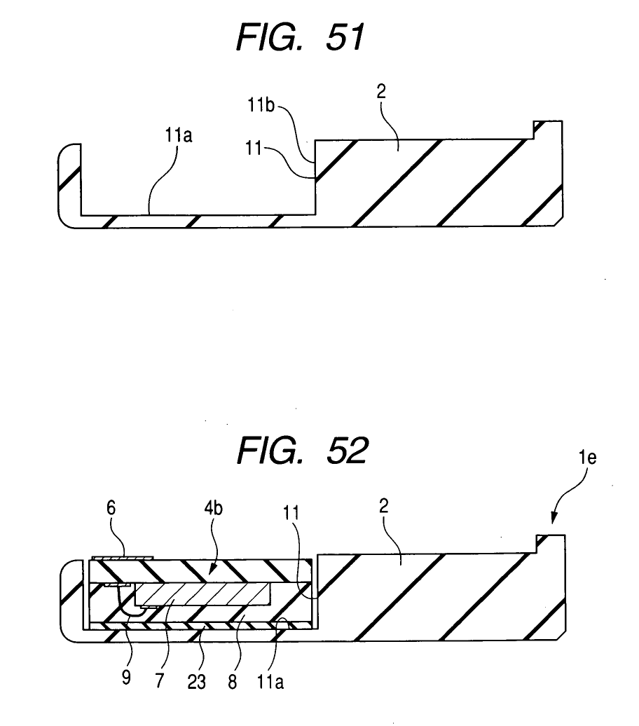

FIG. 51 is a sectional view of the IC card of the sixth embodiment in a manufacturing step;

FIG. 52 is a sectional view of the IC card in a manufacturing step which follows FIG. 51;

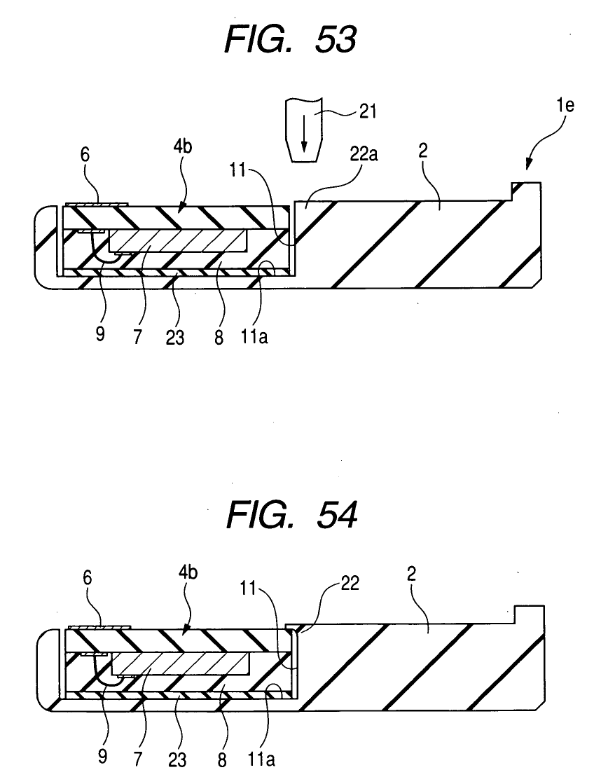

FIG. 53 is a sectional view of the IC card in a manufacturing step which follows FIG. 52;

FIG. 54 is a sectional view of the IC card in a manufacturing step which follows FIG. 53;

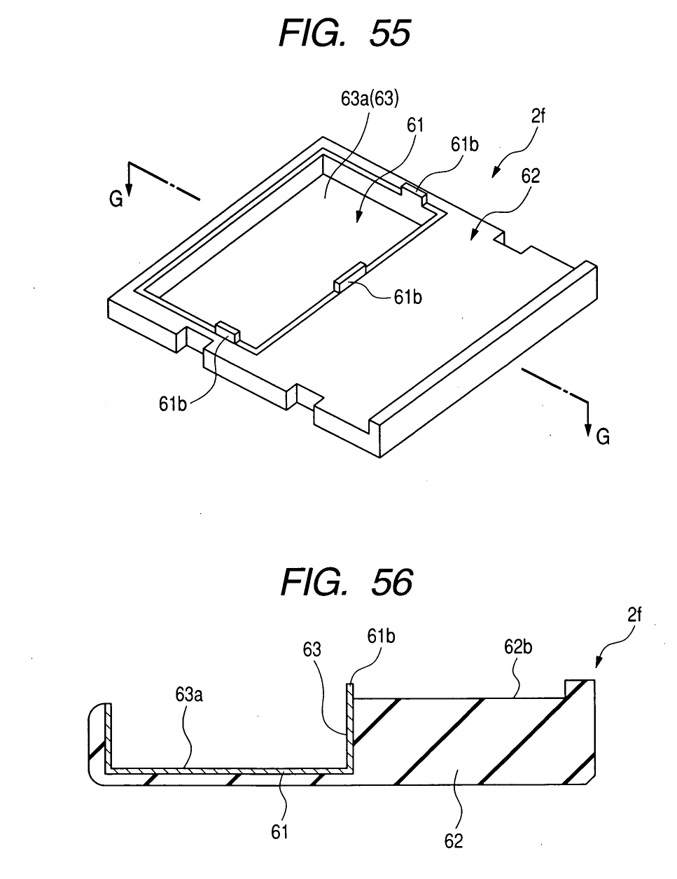

FIG. 55 is a perspective view showing an appearance of a case used in manufacturing an IC card according to a seventh embodiment of the present invention;

FIG. 56 is a sectional view of the case of FIG. 55;

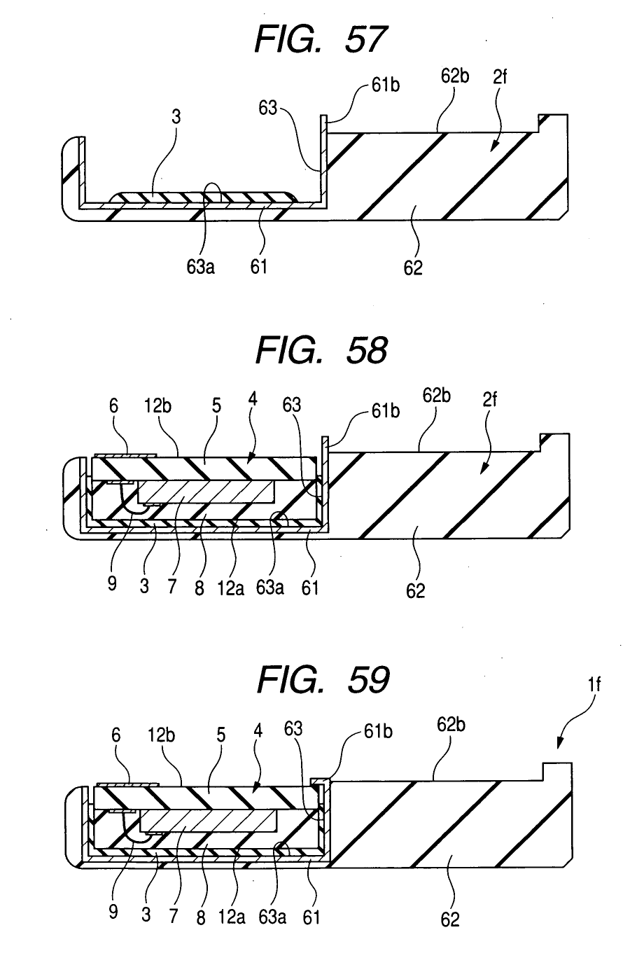

FIG. 57 is a sectional view of the IC card of the seventh embodiment in a manufacturing step;

FIG. 58 is a sectional view of the IC card in a manufacturing step which follows FIG. 57;

FIG. 59 is a sectional view of the IC card in a manufacturing step which follows FIG. 58;

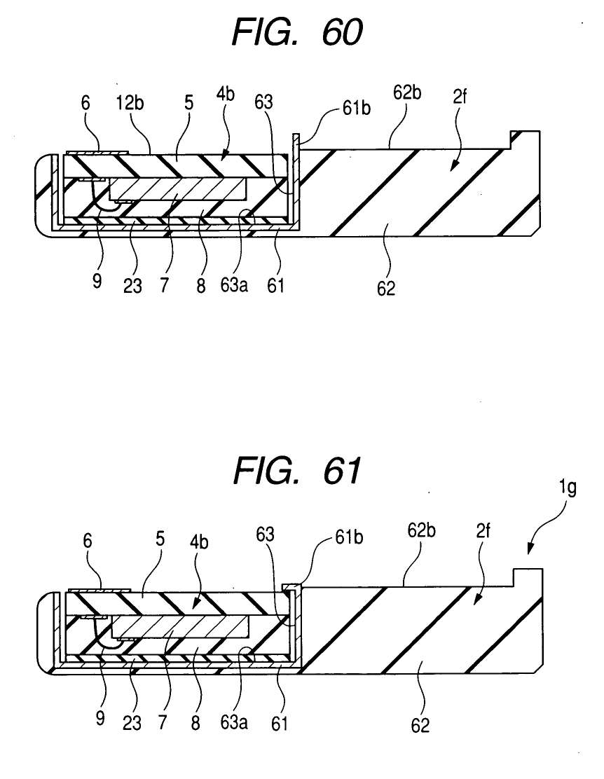

FIG. 60 is a sectional view in a manufacturing step of an IC card according to an eighth embodiment of the present invention;

FIG. 61 is a sectional view of the IC card in a manufacturing step which follows FIG. 60;

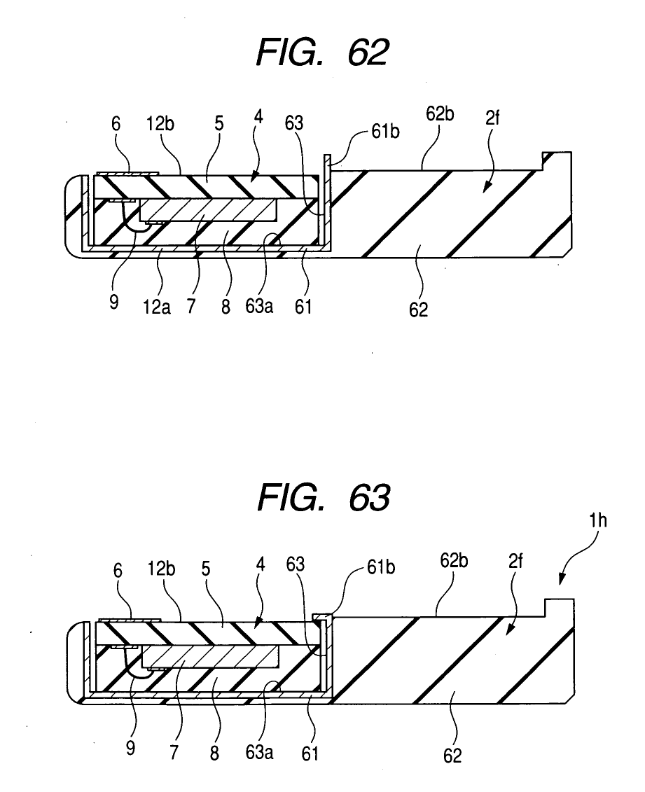

FIG. 62 is a sectional view in a manufacturing step of an IC card according to a ninth embodiment of the present invention;

FIG. 63 is a sectional view of the IC card in a manufacturing step which follows FIG. 62;

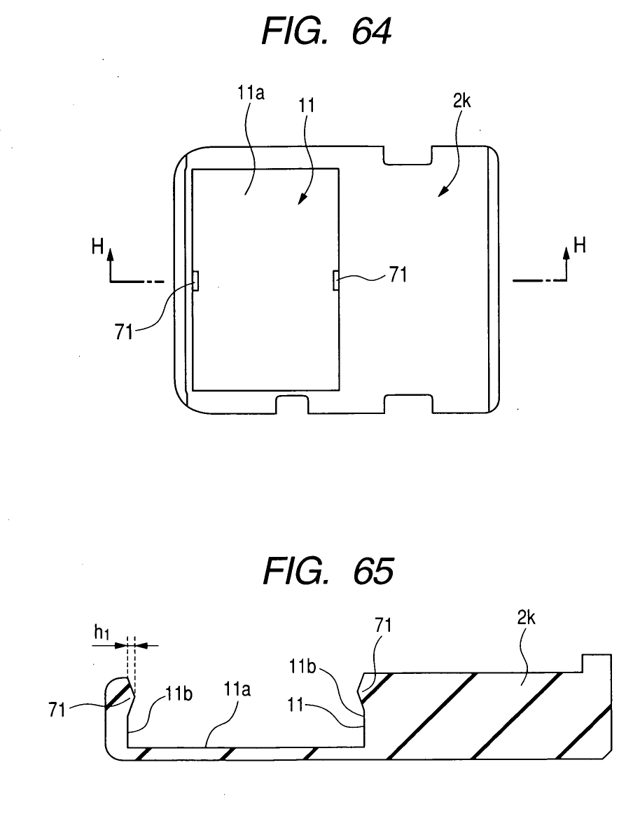

FIG. 64 is a back view of a case used in manufacturing an IC card according to a tenth embodiment of the present invention;

FIG. 65 is a sectional view of the case of FIG. 64;

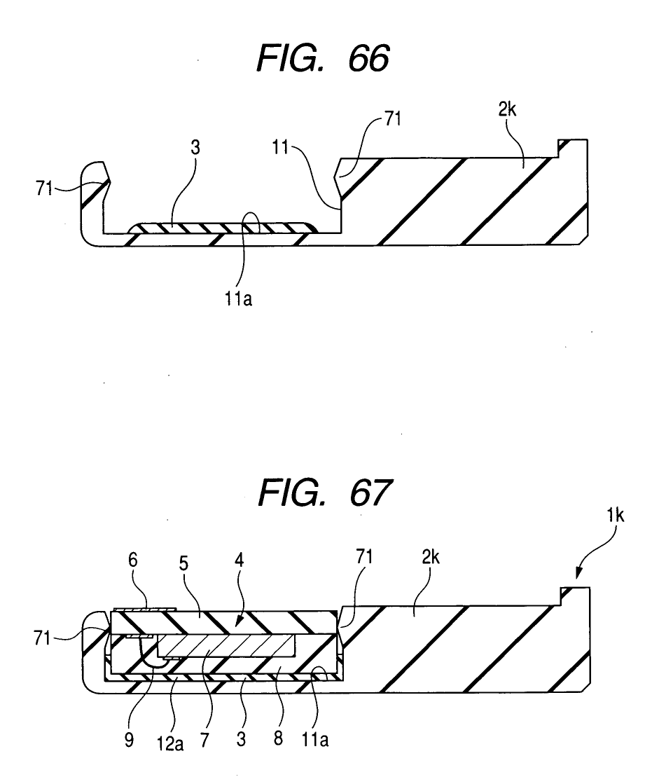

FIG. 66 is a sectional view of the IC card of the tenth embodiment in a manufacturing step;

FIG. 67 is a sectional view of the IC card in a manufacturing step which follows FIG. 66;

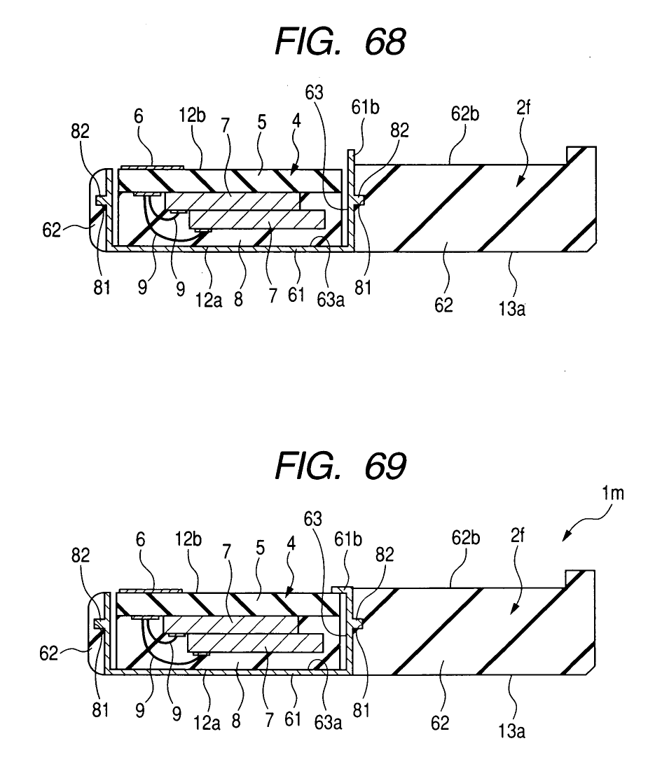

FIG. 68 is a sectional view in a manufacturing step of an IC card according to an eleventh embodiment of the present invention; and

FIG. 69 is a sectional view of the IC card in a manufacturing step which follows FIG. 68.

### DETAILED DESCRIPTION OF PREFERRED EMBODIMENTS

Where required for convenience' sake, the following embodiments will each be described in a divided manner into plural sections or embodiments, but unless otherwise mentioned, they are not unrelated to each other, but are in a relation such that one is a modification or a detailed or supplementary explanation of part or the whole of the other. In the following embodiments, when reference is made to the number of elements (including the number, numerical value, quantity and range), no limitation is made to the number referred to, but numerals above and below the number referred to will do as well unless otherwise mentioned and except the case where it is basically evident that limitation is made to the number referred to. Further, it goes without saying that in the following embodiments their constituent elements (including constituent steps) are not always essential unless otherwise mentioned and except the case where they are considered essential basically obviously. Likewise, it is to be understood that when reference is made to the shapes and positional relation of constituent elements in the following embodiments, those substantially closely similar to or resembling such shapes, etc. are also included unless otherwise mentioned and except the case where a negative answer is evident basically. This is also true of the foregoing numerical value and range.

Embodiments of the present invention will be described in detail hereinunder with reference to the accompanying drawings. In all of the drawings for illustrating the following embodiments, portions having the same functions are identified by like reference numerals, and repeated explanations thereof will be omitted. In the following embodiments, explanations of the same or similar portions will not be repeated except the case where it is necessary to make such explanations.

In the drawings related to the following embodiments, hatching may be omitted even in a sectional view in order to make the drawing easier to see, and even a plan view may be hatched to make it easier to see.

### FIRST EMBODIMENT

An IC card and a manufacturing process for the same card according to this first embodiment will be described below with reference to drawings.

FIG. 1 is a perspective view showing an appearance of an IC card according to this first embodiment, FIG. 2 is a back view (underside view, bottom view, or plan view) of the IC card 1, FIG. 3 is a top view (surface view or plan view) of the IC card 1, and FIG. 4 is a sectional view (sectional side view) taken in a longitudinal direction (line A-A) of the IC card 1.

The IC card 1 of this embodiment shown in FIGS. 1 to 4 is a memory card employable mainly as an auxiliary device in any of various portable electronic devices, including for example information processors such as portable computers, image processors such as digital cameras, and communication devices such as smart phones and portable telephones. It can be loaded to any of these electronic devices. The IC card is in the shape of, for example, a small thin plate (card-like shape) having a quadrangular plane shape. Its outline dimensions may take various values, e.g., about 15 mm long, about 12.5 mm wide and about 1.1 mm thick. It is an MMC of a microsize or a card having a memory stick compatible interface. The IC card 1 may be a card having the same outline standard and function as what is called a multi-media card (hereinafter referred to as “MMC”), or a card having the same outline standard and function as an RS-MMC, or a card having the same outline standard and function as an SD memory card (“SD” card hereinafter), or a card having the same outline standard and function as a memory stick or another memory card.

The IC card 1 of this embodiment shown in FIGS. 1 to 4 includes a case 2 which forms an outline of the IC card and an IC body (semiconductor device) 4 bonded (joined or mounted) and united to the case 2 through a bonding material (adhesive) 3. The case 2 is formed of a resin material such as, for example, a thermoplastic resin.

FIG. 5 is a perspective view showing an appearance of the IC body 4 used in the IC card of this embodiment, FIG. 6 is a back view (bottom view, underside view, or plan view) of the IC body 4, and FIG. 7 is a sectional view taken on line B-B of the IC body shown in FIGS. 5 and 6.

In this embodiment, the IC body 4, which is a portion having a main function of the IC card 1, for example a function as a storage device, includes a wiring substrate 5, a plurality of external connecting terminals (external terminals) 6 formed or disposed on a back surface 5b of the wiring substrate 5, a semiconductor chip 7 mounted (disposed or packaged) on a main surface (surface) 5a of the wiring substrate 5, and a sealing portion (sealing resin or molding resin) 8 for sealing the semiconductor chip 7.

The semiconductor chip 7 is a semiconductor chip for memory (e.g., flash memory) or a semiconductor chip for controlling the semiconductor chip for memory. A single or plural semiconductor chips 7 as necessary are mounted on the wiring substrate 5. The semiconductor chip 7 has plural electrodes (bonding pads) 7a. The electrodes 7a of the semiconductor chip 7 are electrically connected through bonding wires 9 as thin metal wires of, say, gold (Au) to wiring lines (terminals) 10 formed on the wiring substrate 5. That is, plural electrodes 7a of the semiconductor chip 7 are electrically connected to plural wiring lines (terminals) 10 of the wiring substrate 5 through plural bonding wires 9.

The sealing portion 8 is formed on the wiring substrate 5 so as to cover both semiconductor chip 7 and connections (the bonding wires in the illustrated example) between the semiconductor chip 7 and the wiring substrate 5. The sealing portion 8 is formed of a resin material such as, for example, a thermosetting resin material and may contain a filler (e.g., silica filler). For example, the sealing portion 8 can be formed using a filler-containing epoxy resin. Where required, a part (e.g., a passive part) other than the semiconductor chip may be mounted on the wiring substrate 5.

The wiring lines 10 on the main surface 5a of the wiring substrate 5 are electrically connected through conductor layers or the like formed within through holes (not shown) to external connecting terminals 6 formed on the back surface 5b of the wiring substrate 5 which back surface 5b is a main surface located on the side opposite to the main surface 5a. That is, the electrodes 7a of the semiconductor chip 7 packaged (mounted) on the wiring substrate 5 are electrically connected to external connecting terminals 6 formed on the back surface 5b of the wiring substrate 5 through bonding wires 9 and wiring lines (conductor layers) formed in the wiring substrate 5.

As another method for mounting the semiconductor chip 7 there may be adopted a method wherein the semiconductor chip is formed in a shape having bump electrodes (e.g., solder bumps or gold bumps) and is mounted onto the wiring substrate 5 by flip-chip connection (flip-chip bonding) for example. There also may be adopted a method wherein the wiring lines 10 are not formed on the main surface 5a of the wiring substrate 5, but the bonding wires 9 are directly connected through openings of through holes to the external connecting terminals 6 formed on the back surface 5b. In this case, since it is not necessary to form the wiring lines 10 on the wiring substrate 5, it is possible to simplify the manufacturing process and reduce the manufacturing cost. Besides, the IC card 1 can be made thin because it is possible to use a thin wiring substrate.

It is preferable that the case 2 of the IC card 1 be formed using a thermoplastic resin material and that the sealing portion 8 of the IC body 4 be formed using a thermosetting resin material.

The thermosetting resin material used for forming the sealing portion 8 is higher in weathering resistance, in adhesion to the wiring substrate 15 and in chemical stability (the decomposition of resin caused by a secular change is slow and degassing quantity is small) than the thermoplastic resin material used for the case 2. The thermoplastic resin material is lower in elastic modulus than the thermosetting resin material.

Therefore, by forming the sealing portion of the IC body 4 with use of the above thermosetting resin material, it is possible to seal the semiconductor chip 7 and the connections (bonding wires 9 in the illustrated example) between the semiconductor chip 7 and the wiring substrate 5 in high reliability and hence possible to improve the reliability of the IC body 4. Moreover, by forming the case 2 of the IC card 1 with use of the above thermoplastic resin material, it is possible to improve the moldability and shape controllability for the case 2 of the IC card 1 and also improve the releasability in molding of the case 2 of the IC card 1.

As shown in FIG. 4, the case 2 has a recess (depression or groove) 11 for mounting the IC body 4 therein. The IC body 4 is mounted (fitted) and bonded into the recess 11 of the case 2 through the bonding material 3 in such a manner that the mounting surface side (sealing portion 8 side) of the semiconductor chip 7 on the wiring substrate 5 lies inside and a back surface 13b of the IC body 4 (back surface 5b of the wiring substrate 5) as a main surface on the side where the external connecting terminals 6 are formed lies outside. Thus, the IC body 4 is fitted in the recess 11 of the case 2 through the bonding material 3, a surface (upper surface) 12a of the IC body 4 (corresponding to a surface or an upper surface of the sealing portion 8) or both surface 12a and side faces 12c of the IC body 4 are bonded to a bottom 11a of the recess 11 of the case 2 or both bottom 11a and side walls 11b of the recess 11 through the bonding material 3, and a back surface 12b of the IC body 4 (corresponding to the back surface 5b of the wiring substrate 5) as a main surface on the external connecting terminals 6 side is exposed on the back surface 13b side of the case 2, whereby the case 2 and the IC body 4 are united into an IC card 1 having a card-like outline. Thus, the profile (outer surface) of the IC card 1 is formed substantially by the case 2 and the back surface 12b of the IC body 4 (i.e., the back surface 5b of the wiring substrate 5) and the external connecting terminals 6 are exposed to an end side of one main surface (back surface or lower surface) of the IC card 1.

A protuberance (projecting portion) 14a is formed at an end portion (an end portion on the side opposite to the side where the external connecting terminals 6 are arranged) of one or both of a main surface (surface) 13a or the back surface (the main surface on the side opposite to the main surface 13a) 13b of the case 2. In FIGS. 1 to 4, a protuberance 14a is formed at an end portion (an end portion on the side opposite to the side where the recess 11 is formed). The protuberance 14a of the case 2 can function, for example, as a stopper at the time of inserting the IC card 1 into a slot (not shown) or as an anti-slip portion at the time of holding the IC card 1 with fingers. That is, the protuberance 14a is formed at an end portion on the side opposite to the inserting side of the IC card 1 so as to project with respect tot he back surface 13b of the case 2. The protuberance 14a of the case 2 may be omitted if the formation thereof is unnecessary, and the back surface 13b except the recess 11 of the case 2 and the main surface 13a of the case may be made nearly flat.

Recesses (depressions or grooves) 14b are formed as necessary in side faces of the case 2. The recesses 14b formed in side faces of the case 2 are employable for example as stoppers for retaining the IC card 1 within the slot when the IC card is inserted into the slot or as portions for preventing miscontact of the external connecting terminals 6 with non-corresponding terminals. The recesses 14b formed in side faces of the case 2 may be omitted if the formation thereof is unnecessary.

On the back surface 13b side of the case 2 of the IC card 1, plastically deformed portions (projecting portions) 22 are formed at positions near the recess 11 so as to project inwards of the recess 11. As will be described later, the plastically deformed portions 22 are formed by plastic deformation of the case 2 using ultrasonic wave or by cold rolling. In each of the plastically deformed portions 22, for example as shown in FIG. 4, a part of the case 2 (a part of the resin material which constitutes the case 2 or a part of the plastically deformed portion 22) is in an extended state onto the back surface 12b of the IC body 4 (i.e., the back surface 5b of the wiring substrate 5), or, as will be described later, a side wall 11b of the recess 11 of the case 2 is in a contacted state at a position near its upper end with a side face 12c of the IC body 4.

Next, a description will be given below about a manufacturing process for the IC card 1 of this embodiment. First, the IC body 4 is provided. FIGS. 8 to 12 are sectional views (sectional views of a principal portion) in manufacturing steps of the IC body 4 used in the IC card 1 of this embodiment.

For example, the IC card 4 can be manufactured in the following manner.

First, as shown in FIG. 8, there is provided a wiring substrate 15 having wiring lines (terminals) 10 formed on a main surface (surface) 15a thereof and external connecting terminals 6 formed on a back surface (a main surface on the side opposite to the main surface 15a) 15b. As the wiring substrate 15 there may be used a multi-wiring substrate having a plurality of unit wiring substrate portions 16 (corresponding to the wiring substrates 5) from each of which there is fabricated one IC body 4 and which are linked together in an array form. In each unit wiring substrate portion 16, the external connecting terminals 6 formed on the back surface 15b of the wiring substrate 15 are connected electrically through conductor layers or the like formed within through holes to the wiring lines (terminals) 10 formed on the main surface (surface) 15a.

Next, as shown in FIG. 9, a die bonding process is performed to mount (package or dispose) a semiconductor chip 7 (one or plural) for memory and/or control onto each unit wiring substrate portion 16 of the main surface 15a of the wiring substrate 15 through a bonding material (not shown). In case of fixing the semiconductor chip 7 with use of a thermosetting bonding material at the time of mounting the semiconductor chip 7 onto the wiring substrate 15, there may be performed a heat treatment process for thermosetting the bonding material after the mounting of the semiconductor chip 7.

Then, as shown in FIG. 10, a wire bonding process is performed to connect plural electrodes 7a on the semiconductor chip 7 and plural wiring lines 10 on the main surface of the wiring substrate 5 electrically with each other through plural bonding wires 9.

Next, as shown in FIG. 11, a molding process (e.g., transfer molding) is performed to form a sealing portion (sealing resin or molding resin) 18 of for example a thermosetting resin material, which may contain a filler or the like, on the main surface 15a of the wiring substrate 15 so as to cover the semiconductor chip 7 and the bonding wires 9. The sealing portion 18 is formed so as to cover all of the plural unit wiring substrate portions 16 of the wiring substrate 15 (Block Molding Method).

Then, as shown in FIG. 12, by dicing for example, the wiring substrate 15 and the sealing portion 18 are cut for each unit wiring substrate portion 16 into individual (individually divided) IC bodies 4. Each wiring substrate 15 and each sealing portion 18 resulting from the cutting serve as the wiring substrate 5 and the sealing portion 8, respectively. In this way it is possible to manufacture (form) the IC body 4. Accordingly, the IC body 4 is a semiconductor device (semiconductor package) which is in the form of a MAP (Mold Array Package) for example. In this embodiment, the dicing method for the IC body 4 is not limited to dicing, but may be a laser cutting method or a water jet cutting method. In this case, the shape of the IC body 4 is not limited to such a polygonal shape as a rectangular shape, but may be any other desired planar shape.

A case 2 is provided after or before the IC body 4 is provided. FIG. 13 is a perspective view showing an appearance of the case 2 used in manufacturing the IC card 1 of this embodiment, FIG. 14 is a back view (bottom view, underside view, or plan view) of the case 2, and FIG. 15 is a sectional view taken on line C-C of the case 2 of FIGS. 13 and 14.

The manufacturing process for the case 2 may be performed before, after or simultaneously with the manufacturing process for the IC body 4.

The case 2 is formed of a resin material, preferably a thermoplastic resin material, examples of which include polycarbonate, ABS (acrylonitrile butadiene styrene resin), PBT (polybutylene terephthalate), PPE (polyphenylene ether), nylon, LCP (liquid crystal polymer), PET (polyethylene terephthalate), and mixtures thereof. The thermoplastic resin material which forms the case 2 may contain a glass filler (filler), but if the content of the glass filler is as high as that of the sealing portion 8, the hardness of the case 2 becomes high and there arises a fear that for example Au plating of an electrode terminal surface within a slot for insertion and removal of the IC card 1 may be damaged. For this reason it is preferable that the content of the glass filler in the case 2 be lower than that of the sealing portion 8.

Various methods are employable for forming the case 2. For example, the case 2 can be formed by an injection molding method using a mold which has a cavity of a shape conforming to the case 2. The case 2 has a card-like outline formed with a recess (depression or groove) 11 of a shape which permits the IC body 4 to be engaged (fitted or received) therein. Thus, the case 2 formed by injection molding for example has the recess 11 which permits the IC body 4 to be mounted therein.

After the IC body 4 and the case 2 are provided, the IC card 1 is fabricated (assembled) in the following manner. FIGS. 16 to 19 are sectional views of the IC card 1 in manufacturing steps, showing sections of the area corresponding to FIGS. 4 and 14.

First, as shown in FIG. 16, a bonding material (adhesive) 3 is disposed (applied) onto a bottom 11a of the recess 11 of the case 2. As the bonding material 2 there may be used, for example, a thermosetting or reactive curing type bonding material. Further, as the bonding material 3 there may be used, for example, a liquid or gel- or paste-like bonding material.

Next, as shown in FIG. 17, the IC body 4 is mounted into the recess 11 of the case 2 through the bonding material 3. That is, the IC body 4 is mounted into the recess 11 of the case 2 with the bonding material 3 applied thereto. At this time, the IC body 4 is mounted (fitted) into the recess 11 of the case 2 in such a manner that a surface 12a side (i.e., the sealing portion 8 side) of the IC body 4 lies inside (the side opposed to the bottom 11a of the recess 11 in the case 2) and a back surface 12b side (a back surface 5b side of the wiring substrate 5) of the IC body 4 as a main surface with the external connecting terminals 6 formed thereon lies outside. Thus, the external connecting terminals 6 lie on the outer surface side and assume an exposed state on a back surface 13b side of the case 2. Since the recess 11 of the case 2 has a shape conforming to the IC body 4 (a shape permitting the IC body 4 to be mounted therein), the IC body can be engaged (fitted) into the recess 11 of the case 2.

Then, a part of the case 2 (a region 22a near the recess 11) is deformed to fix the IC body 4 to the recess 11 of the case 2. For example, as shown in FIG. 18, a tool 21 is pushed against the region 22a near the recess 11 of the case 2 as shown in FIG. 18 to cause a plastic deformation of the region 22a which is formed of a thermoplastic resin material. As a result, there is formed a plastically deformed portion 22 which is a portion deformed plastically with the tool 21 in the case 2.

For deforming (plastically deforming) the case 2 by means of the tool 21 there may be used ultrasonic wave or cold rolling. This method is preferred because the case 2 can be deformed without causing damage to the IC body 4. According to another method, the case 2 can be deformed by heating with use of the tool 21. The IC body 4 is fixed (temporarily fixed) to the recess 11 of the case 2 by deforming (plastically deforming) the region 22a near the recess 11. The case 2 is deformed by bringing the tool 21 into contact with the region 22a near the recess 11 of the case 2 preferably in such a manner that the tool 21 does not contact the IC body 4, with no damage to the IC body.

FIG. 20 is a plan view showing the region where the case 2 is deformed by pushing the tool 21 thereagainst. FIGS. 21 to 23 are explanatory diagrams showing in what manner the case 2 is deformed by the tool 21. In FIG. 21 there is shown a section (partially enlarged section) of a principal portion before deformation of the case 2, while in FIGS. 22 and 23 there are shown sections (partially enlarged sections) of the principal portion after deformation of the case 2.

The IC body 4 can be fixed (temporarily fixed) to the recess 11 of the case 2 by deforming the case at one or more positions with the tool 21. However, deforming the case 2 at plural positions with the tool 21 is preferred because the IC body 4 can be fixed (temporarily fixed) more positively to the recess 11 of the case 2. For example, as shown in FIG. 20, by pushing the tool 21 against three regions (to-be-deformed regions) 22b to deform (plastically deform) the case 2, the IC body 4 can be fixed (temporarily fixed) more stably to the recess 11 of the case 2. Such plastically deformed portions 22 as referred to above are formed by pushing the tool 21 against the regions 22b.

As shown in FIG. 22, the case 2 is deformed in such a manner that a part of the resin material which constitutes the case 2 extends onto the back surface 12b of the IC body 4 (i.e., the back surface 5b of the wiring substrate 5), allowing resin material portions 22c (comprising the plastically deformed portions 22 of the case) extending onto the back surface 12b of the IC body 4 to hold down the back surface 12b from above, whereby the IC body 4 can be fixed (temporarily fixed) to the recess 11 of the case 2. In this case, at the plastically deformed portions 22 of the case 2, a part of the case 2 (a part of the resin material which constitutes the case) assumes an extending state onto the back surface 12b of the IC body 4 (i.e., the back surface 5b of the wiring substrate 5). Alternatively there may be adopted such a method as shown in FIG. 23 wherein the case 2 is deformed so that a side wall 11b of the recess 11 of the case approaches the IC body 4 (side face 12c thereof), allowing the side wall 11b of the recess 11 to contact and press the side face 12c of the IC body 4, whereby the IC body 4 can be fixed (temporarily fixed) to the recess 11 of the case 2. In this case, the side wall 11b of the recess 11 assumes a state of contact at a position near its upper end with the side face 12c of the IC body 4. Further, both methods shown in FIGS. 22 and 23 may be combined, that is, not only the resin material portions 22c extending onto the back surface 12b of the IC body 4 hold down the back surface 12b of the IC body 4, but also the side wall 11b of the recess 11 in the case 2 contacts and presses the side wall 12c of the IC body 4, whereby the IC body 4 can be fixed (temporarily fixed) to the recess 11 of the case 2.

Before deformation of the case with the tool 21, as shown in FIG. 21, a gap between the IC body 4 and the case 2 in a mounted state of the IC body into the recess 11 of the case 2, (the spacing between the side face 12c of the IC body 4 and the side wall 11b of the recess 11 in the case 2), W₁ may be set at, say, about 50 μm or less, taking into account the dimensional accuracy of the IC body 4 and that of the recess 11 of the case 2. Therefore, as shown in FIGS. 22 and 23, the IC body 4 can be fixed (temporarily fixed) to the recess 11 of the case 2 by merely deforming the region 22a near the recess 11 of the case 2 slightly with the tool 21.

In such a fixed (temporarily fixed) state of the IC body 4 to the recess 11 of the case 2 by deforming a part of the case (the region 22a near the recess 11), the bonding material 3 is cured. In case of the bonding material 3 being a thermosetting bonding material, heat treatment is performed after allowing the IC body 4 to be fixed (temporarily fixed) to the recess 11 by deforming a part of the case (the region 22a near the recess 11), thereby allowing the bonding material 3 to cure. More specifically, in the case where the bonding material 3 is a thermosetting type bonding material, a part of the case 2 is deformed to fix (temporarily fix) the IC body 4 into the recess 11 of the case 2 after mounting of the IC body 4 into the recess 11 and before curing of the bonding material 3, and thereafter the bonding material 3 is cured by heat treatment. In the case where the bonding material 3 is a reactive curing type bonding material, the bonding material cures upon lapse of a predetermined time. More specifically, in case of the bonding material 3 being a reactive curing type bonding material, a part of the case 2 is deformed to fix (temporarily fix) the IC body 4 into the recess 11 of the case 2 after mounting of the IC body into the recess 11 and before complete curing of the bonding material 3, that is, before or during progression of a curing reaction of the bonding material 3, followed by standing for a predetermined time to let the bonding material 3 cure completely. Upon curing of the bonding material 3, the IC body 4 is bonded and united firmly to the case 2 through the bonding material.

In this way there is formed an IC card 1 comprising the IC body 4 and the case 2 which have been bonded and united through the bonding material 3. A generally card-shaped outline of the IC card 1 is formed by the back surface 12b of the IC body 4 (the back surface 5b of the wiring substrate 5) and the other outer surface portion than the recess 11 of the case 2. Thus, such an IC card 1 of this embodiment as shown in FIGS. 1 to 4 is fabricated.

In the case where the material of the case 2 is a transparent material having permeability to ultraviolet light, a UV curing adhesive may be used as the bonding material 3 and cured by the radiation of ultraviolet light thereto. This is effective in management of the IC body 4 because the case 2 can be cured locally at a desired timing.

In this embodiment, the IC card 1 is fabricated by bonding (joining) and uniting the IC body 4 to the case 2 through the bonding material 2. The case 2 can be formed for example by an injection molding method using a thermoplastic resin material and thus can be fabricated in a relatively inexpensive manner. On the other hand, the manufacturing cost of the IC body 4 is apt to become high because the IC body 4 is fabricated using the wiring substrate 15. However, by making the IC body 4 smaller in size than the IC card 1, it is possible to increase the number of IC bodies 4 capable of being obtained from one wiring substrate 15 and hence possible to reduce the manufacturing cost of each IC body 4. Since the IC body 4 is bonded to the inexpensive case 2 which is larger than the IC body 4 and which substantially defines the outline of the IC card 1, thereby forming the IC card 1, it is possible to reduce the manufacturing cost of the IC card.

In this embodiment, the IC card 1 is fabricated by bonding and uniting the small-sized IC body 4 to the case 2 which is larger than the IC body. Therefore, by making the IC body 4 common and changing the size of the case 2, it is possible to fabricate IC cards of various specifications or sizes. The case 2 may be made common and the size of the IC body 4 may be changed arbitrarily. Thus, it is possible to reduce the development cost and manufacturing cost of the IC card.

In this embodiment, moreover, since the IC card 1 is fabricated by bonding and uniting the IC body 4 to the case 2 through the bonding material 3, it is possible to use different resin materials for the sealing portion 8 of the IC body 4 and the case 2, respectively. In the IC body 4, the resin material of the sealing portion 8 for sealing the semiconductor chip 7 is required to have high weathering resistance, adhesion and chemical stability (the decomposition of resin caused by a secular change should be slow and the degassing quantity should be small). To meet this requirement, it is preferable to use a thermosetting resin material (e.g., an epoxy resin containing silica filler) as the material of the sealing portion 8. With such a material, it is possible to improve the reliability of the IC card 1. As the resin material for forming the case 2 of the IC card 1 it is preferable to use a thermoplastic resin (thermoplastic plastic material) which is less expensive and can shorten TAT (turn around time). With such a material, it is possible to reduce the manufacturing cost of the IC card 1.

The thickness t₁ of the IC card 1 thus fabricated is required to be high in accuracy. If the IC card thickness t₁ varies and is larger than a standard value (target value), there is a fear that a coating such as Au plating formed on an electrode surface within a slot (not shown) may be damaged at the time of inserting or pulling out the IC card 1 into or from the slot. If the IC card thickness t₁ varies and is smaller than the standard value (target value), there is a fear that a contact imperfection may occur between external connecting terminals 6 of the IC card 1 and the electrode in the slot. Therefore, it is necessary that an IC card whose thickness is outside the standard value be sorted as a defective card and removed. This leads to a lowering of the IC card production yield. Thus, it is desired to fabricate the IC card 1 with high accuracy so that its thickness t₁ conforms to the standard value (target value).

However, since it takes time for the bonding material 3 to cure, if the IC body 4 shifts from the case 2 after mounting of the IC body 4 into the recess 11 of the case 2 through the bonding material 3 and during curing (before completion of curing) of the bonding material 3, the final thickness t₁ of the IC card 1 after curing of the bonding material 3 becomes deviated from the standard value (target value).

FIG. 24 is a sectional view of a comparative IC card 101 which has been fabricated by curing the bonding material 3 without deformation of the case 2 unlike this embodiment after mounting the IC body 4 into the recess 11 of the case 2 through the bonding material 3. FIG. 24 corresponds to FIG. 4 in this embodiment.

After mounting the IC body 4 into the recess 11 of the case 2 through the bonding material 2, if the IC body 4 shifts from the case 2 during curing (before completion of curing) of the bonding material 3, for example if the bonding material 3 cures in a floating state of the IC body 4 over the bonding material as shown in FIG. 24, the final thickness t₁ of the IC card 101 after curing of the bonding material 3 is deviated from the standard value (target value) and becomes larger. This is likely to cause a problem such as damage of a coating, e.g., Au plating formed on the electrode surface in the slot at the time of inserting or pulling out the IC card 101 into or from the slot. Therefore, it is necessary that an IC card 101 having a final thickness t₁ after curing of the bonding material 3 deviated from the standard value (target value) be sorted as a defective card and removed. This causes a lowering of the production yield of the IC card.

Also conceivable, though different from this embodiment, is a method wherein the bonding material 3 is cured while holding down the IC body 4 against the case 2 mechanically with use of a separate presser jig (presser device) to prevent movement of the IC body 4 from the case 2. According to this method, however, the curing process for the bonding material 3 becomes complicated and the throughput thereof is deteriorated.

In this embodiment, after mounting the IC body 4 into the recess 11 of the case 2 through the bonding material 3, a part of the case 2 is deformed to fix (temporarily fix) the IC body 4 to the case 2 and in this state the bonding material 3 is cured. More particularly, the region 22a near the recess 11 of the case 2 is deformed to fix (temporarily fix) the IC body 4 to the recess 11 of the case 2 before complete curing of the bonding material 3 (before or during curing, preferably before curing) of the bonding material and in this state the bonding material 3 is cured. Thus, it is possible to prevent movement of the IC body 4 from the case 2 during curing (before completion of curing) of the bonding material 3. Consequently, the IC card 1 can be fabricated with high accuracy so that its final thickness t₁ conforms to the standard value (target value). As a result, it is possible to improve the production yield of the IC card and reduce the IC card manufacturing cost.

As to the protuberance 14a of the IC card 1, it is formed so as to become thicker than the thickness t₁ of the IC card 1 which is defined by the standard value. As described earlier, this is because the protuberance 14a functions as a stopper at the time of insertion of the IC card 1 into the slot or as an anti-slip portion at the time of holding the IC card with fingers.

In this embodiment, since the bonding material 3 is cured in a state in which the IC body 4 is fixed (temporarily fixed) to the case 2 by deforming a part of the case, it is not necessary to hold down the IC body 4 against the case 2 with use of a separate presser jig or the like during curing of the bonding material 3. Therefore, it is possible to simplify the curing process of the bonding material 3 and improve the throughput of the same process. As a result, it is possible to improve the productivity of the IC card and reduce the IC card manufacturing cost.

### SECOND EMBODIMENT

FIG. 25 is a back view (bottom view, underside view, or plan view) of a case 2a used in manufacturing an IC card 1a according to this second embodiment and FIG. 26 is a sectional view taken on line D-D of the case 2a of FIG. 25. FIGS. 25 and 26 correspond substantially to FIGS. 14 and 15, respectively, in the previous first embodiment. Further, FIGS. 27 to 30 are sectional views of the IC card 1a in manufacturing steps, showing the same region as in FIG. 26. FIGS. 27 to 30 correspond substantially to FIGS. 16 to 19, respectively, in the previous first embodiment.

Also in this second embodiment, an IC body 4 is provided in the same way as in the first embodiment. Then, as shown in FIGS. 25 and 26, there is provided a case 2a used in manufacturing the IC card 1a of this embodiment. A manufacturing process for the case 2a may be performed before, after or simultaneously with the manufacturing process for the IC body 4.

The case 2a used in manufacturing the IC card 1a of this embodiment has almost the same structure as the case 2 used in the first embodiment except that protuberances 31 are formed on a back surface (lower surface or main surface) 13b of the case 2a which back surface is a main surface on the mounting side of the IC body 4. More specifically, like the case 2, the case 2a has a recess 11 in which the IC body 4 can be fitted, but unlike the case 2, a protuberance (lug or lug-like portion) 31 is formed in a region near the recess 11 of the back surface 13b of the case 2a. It is effective to provide at least one protuberance 31, but it is preferable that plural protuberances 31 be provided. For example, as shown in FIG. 25, three protuberances 31 may be provided near the recess 11 of the back surface 13b of the case 2a. The case 2a is formed using the same material as that of the case 2 in the first embodiment and can be fabricated by the same method as that for the case 2.

After the case 2a and IC body 4 of such structures are provided, as shown in FIG. 27, the bonding material 3 is disposed (applied) onto a bottom 11a of the recess 11 of the case 2a in the same way as in the first embodiment. Then, as shown in FIG. 28, the IC body 4 is mounted (fitted) into the recess 11 of the case 2a through the bonding material 3 in the same manner as in the first embodiment.

Next, a region near the recess 11 of the case 2a is deformed to fix (temporarily fix) the IC body 4 into the recess 11 of the case 2a in the same manner as in the first embodiment. At this time, in this second embodiment, a tool 21 is pushed against the protuberances 31 of the case 2a as shown in FIG. 29 to induce a plastic deformation of the protuberances 31 as in FIG. 30. As a result of such plastic deformation of the protuberances 31 of the case 2a there are formed plastically deformed portions 22. Since the protuberances 31 of the case 2a are plastically deformed using the tool 21, the protuberances 31 are flattened and, after the deformation, the back surface 13b of the case 2a becomes free of the protuberances, that is, becomes flat. It is preferable that a planar shape of the protuberances 31 of the case 2a be smaller than that of a lower surface 21a of the tool 21, whereby the whole of each protuberance 31 can be deformed by the tool 21 and the back surface 13b of the case 2a can be flattened more accurately.

Thus, in a state in which the region (the protuberances 31 in this embodiment) near the recess 11 of the case 2a is deformed to fix (temporarily fix) the IC body 4 into the recess 11 of the case 2a, the bonding material 3 is allowed to cure in the same way as in the first embodiment, whereby there is formed an IC card 1a comprising the IC body 4 and the case 2a which are bonded and united through the bonding material 3.

Also in this second embodiment it is possible to obtain substantially the same effects as in the first embodiment.

Further, in this embodiment, protuberances 31 to be deformed by the tool 21 are formed beforehand on the case 2a which is used in manufacturing the IC card 1a and the tool 21 is pushed against the protuberances 31 to deform (plastically deform) the protuberances. Therefore, with the IC body 4 fixed temporarily by the deformation of the case 2a, the back surface 13b of the case 2a after the deformation can be put in a more flat condition free of unevenness. Thus, the back surface 13b of the case 2a of the IC card 1a obtained finally after curing of the bonding material 3 can be put in a more flat condition and it is possible to prevent the occurrence of any unnecessary unevenness on the outer surface (back surface) of the IC card 1a.

### THIRD EMBODIMENT

FIG. 31 is a perspective view showing an appearance of a case 2b used in manufacturing an IC card 1b according to a third embodiment of the present invention, FIG. 32 is a back view (bottom view, underside view, or plan view) of the case 2b of FIG. 31, and FIG. 33 is a sectional view taken on line E-E of the case 2b of FIGS. 31 and 32. FIGS. 31 to 33 correspond substantially to FIGS. 13 to 15, respectively. FIGS. 34 to 37 are sectional views of the IC card 1b in manufacturing steps, showing the same region as FIG. 33. FIGS. 34 to 37 correspond substantially to FIGS. 16 to 19, respectively. FIG. 38 is a sectional view showing a comparative IC card 102.

Also in this third embodiment there is provided an IC body 4 in the same way as in the first embodiment. Then, as shown in FIGS. 31 to 33, there is provided a case 2b used in manufacturing the IC card 1b of this embodiment. A manufacturing process for the case 2b may be performed before, after or simultaneously with the manufacturing process for the IC body 4.

The case 2b used in manufacturing the IC card 1b of this embodiment has substantially the same structure as the case 2 used in the first embodiment. More specifically, the case 2b, like the case 2, has a recess 11 which permits the IC body 4 to be fitted therein, but unlike the case 2 a plurality of protuberances 41 are provided on a bottom 11a of the recess 11 of the case 2b. The height of each protuberance 41 (the height in a direction perpendicular to the bottom 11a of the recess 11) may be set at, say, about 10 to 200 μm. It is effective to provide at least one protuberance 41 on the bottom 11a of the recess 11, but it is preferable to provide plural such protuberances 31. The provision of three or more such protuberances 31 is more preferable because the stability of the IC body 4 is improved when the IC body is mounted into the recess 11. For example, as shown in FIGS. 31 and 32, protuberances 41 may be formed at five positions on the bottom 11a of the recess 11. The case 2b is formed using the same material as that of the case 2 in the first embodiment and can be fabricated in the same way as in the first embodiment.

After the case 2b and IC body 4 of such structures are provided, the bonding material 3 is disposed (applied) onto the bottom 11a of the recess 11 of the case 2b in the same manner as in the first embodiment, as shown in FIG. 34. Then, the IC body 4 is mounted (fitted) into the recess 11 through the bonding material 3 in the same manner as in the first embodiment, as shown in FIG. 35.

At this time, since plural protuberances 41 are formed on the bottom 11a of the recess 11 of the case 2b, upper surfaces of the protuberances 41 come into contact with a surface 12a of the IC body 4 (upper surface of the sealing portion 8) and a space (gap) 42 having a height equal to the height of each protuberance 41 is formed between the surface 12a of the IC body 4 and the bottom 11a of the recess 11. The bonding material 3 is stored in the space 42.

Next, in the same way as in the first embodiment, a region near the recess 11 of the case 2b is deformed to fix (temporarily fix) the IC body 4 into the recess 11 of the case 2b. At this time, in the same manner as in the first embodiment, a tool 21 is pushed against a region 22a near the recess 11 of the case 2b as shown in FIG. 36 to deform the region 22a plastically as in FIG. 37. Then, in a state in which the region near the recess 11 of the case 2 is deformed (plastically deformed) to fix (temporarily fix) the IC body 4 into the recess 11, the bonding material 3 is cured in the same manner as in the first embodiment, whereby there is formed (fabricated) an IC card 1b comprising the IC body 4 and the case 2b which are bonded and united through the bonding material 3.

If the IC body 4 is pushed too strong after mounting the IC body into the recess 11 of the case 2 through the bonding material 3 and before curing of the bonding material, the bonding material overflows to the outer surface side from a gap between a side wall 11b of the recess 11 of the case 2 and a side face 12c of the body 4, with a consequent likelihood of the bonding material 3 adhering to a back surface 13b of the case 2 and a back surface 12b of the IC body 4, as in the comparative IC card of FIG. 38. Such a phenomenon is apt to occur particularly in case of using a liquid or gel- or paste-like bonding material as the bonding material 3. If the bonding material 3 adheres to the back surface 13b of the case 2 or the back surface 12b of the IC body 4, there is a possibility that the tool 21 may be stained by the bonding material or the bonding material may adhere to external connecting terminals 6. If the bonding material 3 adheres to the external connecting terminals 6, there occurs a contact imperfection between the external connecting terminals of the IC card 102 and an electrode formed within a slot upon insertion of the IC card 102 into the slot. Therefore, it is necessary that an IC card 102 with the bonding material 3 adhered to the outer surface be sorted as a defective card and removed. This leads to a lowering of the IC card production yield.

In this embodiment, since plural protuberances 41 are formed on the bottom 11a of the recess 11 of the case 2b, when the IC body 4 is mounted into the recess 11 of the case 2 through the bonding material 3, the space 42 having a height equal to the height of each protuberance 41 and storing the bonding material 3 therein is formed between the surface 12a of the IC body 4 and the bottom 11a of the recess 11. Therefore, even if the IC body 4 is pushed strongly after mounting the IC body 4 into the recess 11 of the case 2b through the bonding material 3 and before curing of the bonding material, the space 42 between the surface 12a of the IC body 4 and the bottom 11a of the recess 11 does not change and the bonding material 3 can be present within the space 42, so that the bonding material 3 does not overflow to the outer surface side from the gap between the side wall 11b of the recess 11 of the case 2b and the side face 12c of the IC body 4. Thus, even if a liquid or gel- or paste-like bonding material is used as the bonding material 3, it is possible to prevent overflow of the bonding material 3 to the outer surface side from the gap between the case 2b and the IC body 4. Consequently, the bonding material 3 can be prevented from adhering to the back surface 13b of the case 2b and the back surface 12b of the IC body 4 and adhering to the external connecting terminals 6. As a result, it is possible to improve the production yield of the IC card 1b.

The shape of the protuberances 41 formed on the bottom 11a of the recess 11 of the case 2b can be changed to various shapes. FIG. 39 is a perspective view showing a modified example (another form) of the case 2b used in this embodiment and FIG. 40 is a back view (bottom view, underside view, or plan view) thereof, corresponding to FIGS. 31 and 32, respectively.

As shown in FIGS. 39 and 40, a band-like protuberance 41a having the same function as the protuberances 41 may be formed on the bottom 11a of the recess 11 of the case 2b. In this case, it is preferable that the band-like protuberance 41a be formed on an end side corresponding to the side where the external connecting terminals 6 are positioned. With the band-like protuberance 41a, it is possible to control the flow of the bonding material 3 and prevent more positively the bonding material 3 from overflowing to the outer surface side through the gap between the recess 11 of the case 2b and the IC body 4 on the side where the external connecting terminals 6 are positioned, whereby the bonding material 3 can be prevented more positively from adhering to the external connecting terminals 6.

In this embodiment, after mounting the IC body 4 into the recess 11 of the case 2b through the bonding material 3, a part of the case 2b is deformed (plastically deformed) to fix (temporarily fix) the IC body 4 to the recess 11 of the case 2b and in this state the bonding material 3 is cured, as in the first embodiment. Therefore, it is possible to obtain substantially the same effect as in the first embodiment such that the IC card 1b can be fabricated with high accuracy in a state of its final thickness after curing of the bonding material 3 being in conformity with the standard value (target value). In this embodiment, unlike the first embodiment, even if the bonding material 3 is cured without deformation (plastic deformation) of the case 2b after mounting the IC body 4 into the recess 11 of the case 2b through the bonding material 3, it is possible to prevent overflow of the bonding material 3 from the gap between the case 2b and the IC body 4 and hence possible to prevent the bonding material 3 from adhering to the back surface 13b of the case 2b, the back surface 12b of the IC body 4 and further to the external connecting terminals 6. Thus, it is possible to obtain such an outstanding effect.

Of course, the contents of this embodiment may be combined with the second embodiment. In this case, it is possible to further enhance the mounting stability of the IC body 4 with respect to the case (2b).

### FOURTH EMBODIMENT

FIG. 41 is a sectional view of an IC card 1c according to a fourth embodiment of the present invention, corresponding substantially to FIG. 37 in the third embodiment. FIGS. 42 and 43 are sectional views (sectional views of a principal portion) in manufacturing steps of an IC body (semiconductor device) 4a used in the IC card 1c of FIG. 41, corresponding to FIGS. 11 and 12, respectively, in the first embodiment.

In the previous third embodiment, plural protuberances 41 are formed on the bottom 11a of the recess 11 of the case 2b and the IC body 4 is mounted through the bonding material 3 to the case 2b having the plural protuberances 41, but in this fourth embodiment, instead of forming the plural protuberances 41 on the bottom 11a of the recess 11 of the case 2b, plural protuberances 41b are formed on a surface 12a of an IC body 4a (corresponding to the IC body 4) (upper surface of the sealing portion 8) and the IC body 4a having the plural protuberances 41b is mounted into the recess 11 of the case 2 through the bonding material 3. The construction and manufacturing process of this embodiment are about the same as in the third embodiment except that the plural protuberances 41b are formed on the surface 12a of the IC body 4 (upper surface of the sealing portion 8) instead of forming the plural protuberances 41 on the bottom 11a of the recess 11 of the case.

More specifically, after the structure of FIG. 10 is obtained in the same way as in the first embodiment, a molding process (e.g., transfer molding) is performed, as shown in FIG. 42, to form a sealing portion 18 of a thermosetting resin material on the main surface 15a of the wiring substrate 15 so as to cover the semiconductor chip 7 and the bonding wires 9. The sealing portion 18 is formed so as to cover all of plural unit wiring substrate portions 16 of the wiring substrate 15. In this embodiment, the sealing portion 18 is formed so that in each unit wiring portion 16 there are formed plural protuberances 41b on an upper surface 18a of the sealing portion 18, the protuberances 41b being formed of the material which constitutes the sealing portion 18.

Next, as shown in FIG. 43, the wiring substrate 15 and the sealing portion 18 are cut for example by dicing for each unit wiring substrate portion 16 into individual (individually divided) IC bodies 4a. Each wiring substrate 15 and each sealing portion 18 thus obtained by the cutting process become the wiring substrate 5 and the sealing portion 8, respectively. In this way it is possible to fabricate the IC body 4a. The shape, size and number of the protuberances 41b in the IC body 4a may be set at about the same as those of the protuberances 41 formed on the bottom 11a of the recess of the case 2b in the third embodiment.

By using the IC body 4a instead of the IC body 4 and using the case 2 instead of the case 2b it is possible to fabricate (assemble) an IC card 1c as in the third embodiment.

Also in this fourth embodiment it is possible to obtain about the same effects as in the third embodiment.

More particularly, as shown in FIG. 41, by forming plural protuberances 41b on the surface 12a of the IC body 41, a space 42 having a height equal to the height of each protuberance 41b and with the bonding material 3 stored therein is formed between the surface 12a of the IC body 4a and the bottom 11a of the recess 11 of the case 2 when mounting the IC body 4a into the recess 11 of the case 2 through the bonding material 3. Therefore, even if the IC body 4a is pushed strongly after mounting the IC body 4a into the recess 11 of the case 2 through the bonding material 3 and before curing of the bonding material 3, the space 42 formed between the surface 12a of the IC body 4a and the bottom 11a of the recess 11 of the case 2 does not change and the bonding material 3 can be present in the space 42, so that the bonding material 3 can be prevented from overflowing to the outer surface side from the gap between a side wall 11b of the recess 11 of the case 2 and a side face 12c of the IC body 4a. Consequently, it is possible to prevent the bonding material 3 from adhering to a back surface 13b of the case 2, a back surface 12b of the IC body 4a and further to the external connecting terminals 6. As a result, it is possible to improve the production yield of the IC card.

Of course, the contents of this embodiment may be combined with the second embodiment, whereby it is possible to further enhance the mounting stability of the IC body 4a to the case 2.

### FIFTH EMBODIMENT

FIG. 44 is a back view (bottom view, underside view or plan view) of a case 2c used in manufacturing an IC card 1d of this fifth embodiment and FIG. 45 is a sectional view taken on line F-F of the case 2c of FIG. 44, corresponding to FIGS. 32 and 33, respectively, in the third embodiment. FIGS. 46 and 47 are sectional views of the IC card 1d in manufacturing steps, showing sections of the same region as FIG. 45 and corresponding substantially to FIGS. 35 and 37, respectively, in the third embodiment.

In the previous third embodiment the plural protuberances 41 are provided on the bottom 11a of the recess 11 of the case 2b, but in this fifth embodiment not only plural protuberances 41 but also a recess (depression or groove) 51 as a sump for the bonding material 3 is formed in a bottom 11a of a recess 11 of a case 2c (corresponding to the cases 2, 2a and 2b). The construction and manufacturing process of this embodiment are about the same as in the third embodiment except that the recess 51 as a sump for the bonding material 3 is formed in addition to the plural protuberances 41 in the bottom 41a of the recess 11 of the case 2c.

More specifically, the case 2c used in manufacturing an IC card 1d of this embodiment can be fabricated in the same way as in the manufacture of the cases 2, 2a and 2c in the first to fourth embodiments, but in this fifth embodiment, as shown in FIGS. 44 and 45, a recess 51 as a sump for the bonding material 3 is formed in the bottom 11a of the recess 11 of the case 2c in addition to such plural protuberances 41 as in the case 2b used in the third embodiment. It is preferable that the recess 51 be formed like a groove along end portions of the bottom 11a of the recess 11 of the case 2c, as shown in FIGS. 44 and 45.

By using the case 2c instead of the case 2b it is possible to fabricate (assemble) the IC card 1d as in the third embodiment.

More particularly, as shown in FIG. 46, the bonding material 3 is disposed (applied) onto the bottom 11a of the recess 11 of the case 2c and thereafter the IC body is mounted (fitted) into the recess 11 through the bonding material 11. Then, in the same way as in the third embodiment, a region near the recess 11 of the case 2c is deformed (plastically deformed) to fix (temporarily fix) the IC body 4 into the recess 11 of the case 2c and thereafter the bonding material 3 is cured, as shown in FIG. 47, whereby there is formed an IC card 1d comprising the IC body 4 and the case 2c which are bonded and united through the bonding material 3.

As in this embodiment, by forming the plural protuberances 41 and the recess 51 in the bottom 11a of the recess 11a of the recess 11 of the case 2c, a space 42 having a height equal to the height of each protuberance 41 and with the bonding material 3 stored therein is formed between the surface 12a of the IC body 4 and the bottom 11a of the recess 11 when mounting the IC body 4 into the recess 11 through the bonding material 3, further, the bonding material 3 is stored also in the recess 51. Even if the IC body 4 is pushed strongly after mounting the IC body 4 into the recess 11 of the case 2c through the bonding material 3 and before curing of the bonding material, the space 42 between the surface 12a of the IC body 4 and the bottom 11a of the recess 11 does not change and the bonding material 3 can be present within the space 42, so that the bonding material 3 can be prevented from overflow to the outer surface side through the gap formed between a side wall 11b of the recess 11 of the case 2c and a side face 12c of the IC body 4. In this embodiment, moreover, since the recess 51 as a sump for the bonding material 3 is formed in the bottom 11a of the recess 11 of the case 2c, even if the amount of the bonding materail 3 applied to the bottom 11a of the recess 11 is too large, the bonding material can be stayed within the recess 51 and hence it is possible to prevent more accurately such a surplus bonding material 3 from overflow through the gap between the side wall 11b of the recess 11 of the case 2c and the side wall 12c of the IC body 4. Consequently, the bonding material 3 can be prevented more accurately from adhering to the back surface 13b of the case 2c, the back surface 12b of the IC body 4 and further to the external connecting terminals 6. As a result, it is possible to further improve the production yield of the IC card. Moreover, by forming the recess 51 groovewise in end portions of the bottom 11a of the recess 11 of the case 2c, the flowing up of the bonding material 3 along the side wall 11b of the recess 11 can be prevented more effectively.

As to the shape of the case 2c, it is not always necessary to form both recess 51 and protuberances 41. For example, only the recess 51 or only the protuberances 41 may be formed, depending on desired reliability.

Of course, the contents of this fifth embodiment may be combined with the second embodiment. In this case, it is possible to further enhance the mounting stability of the IC body 4 with respect to the case (2c). Further, the production yield of the IC card can be more improved in comparison with a combination of the second and third embodiments.

### SIXTH EMBODIMENT

In the first embodiment the IC body (semiconductor device) 4 is bonded to the case 2 through the liquid or gel- or paste-like bonding material 3, but in this sixth embodiment the IC body is bonded to the case 2 using a filmy bonding material or an adhesive film (adhesive sheet).

FIGS. 48 to 50 are sectional views of an IC body (semiconductor device) 4b in manufacturing steps according to a sixth embodiment of the present invention. FIGS. 51 to 54 are section views in manufacturing steps of an IC card 1e used in this embodiment, showing sections of a region corresponding substantially to FIG. 4 in the first embodiment.

An IC body 4b can be fabricated, for example, in the following manner.

First, the same processes (die bonding process, wire bonding process, and molding process) as in the first embodiment are performed to afford the structure of FIG. 48 which is the same as that of FIG. 11. Thereafter, as shown in FIG. 49, an adhesive film (adhesive sheet) 23 as a double-coated adhesive film is affixed (bonded) to the upper surface 18a of the sealing portion 18. The adhesive film 23 contains, for example, a thermoplastic bonding material or a reactive curing type bonding material. The adhesive film 23 is a filmy member which is adhesive on both main surfaces thereof. Though not shown, the adhesive film 23 may be covered with a separator film for protection thereof until mounting of the IC body into the recess 11 of the case 2. With such a separator film, the surface of the adhesive film 23 can be prevented from being stained or damaged.

Next, in the same way as in the first embodiment, as shown in FIG. 50, the wiring substrate 15, sealing portion 1 and adhesive film 23 are cut for each unit wiring substrate portion 16 by dicing or the like into individual (individually divided) IC bodies 4b. That is, the IC body 4 in the first embodiment with the double-coated adhesive film 23 affixed (bonded) to the upper surface of the sealing portion 8 corresponds to the IC body 4b.

As shown in FIG. 51, the same case 2 as in the first embodiment is provided after or before the provision of the IC body 4b. A manufacturing process for the case 2 may be performed before, after and simultaneously with the manufacturing process for the IC body 4b.

After the case 2 and IC body 4b of such structures are provided, the IC body 4b is mounted (fitted) into the recess 11 of the case 2, as shown in FIG. 52. At this time, it is not necessary to dispose (apply) the bonding material 3 onto the bottom 11a of the recess 11. In this embodiment, the IC body 4b is mounted into the recess 11 of the case 2 in such a manner that the adhesive film 23 in the IC body comes into opposed contact with the bottom 11a of the recess 11. The adhesive film 23 in the IC body 4b can function as a bonding material for bonding the IC body to the case 2.

Next, as in the first embodiment, a region near the recess 11 of the case 2 is deformed to fix (temporarily fix) the IC body 4b into the recess 11 of the case 2. At this time, as in the first embodiment, the tool 21 is pushed against the region 22a near the recess 11 of the case 2 as shown in FIG. 53 to deform the region 22a plastically as in FIG. 54.

Thus, in a state in which the region near the recess 11 of the case 2 is deformed (plastically deformed) to fix (temporarily fix) the IC body 4b into the recess 11 of the case 2, the adhesive film 23 is cured, whereby there is formed an IC card 1e comprising the IC body 4b (IC body 4) and the case 2 which are bonded and united through the adhesive film 23. More specifically, one main surface of the adhesive film 23 is bonded to the sealing portion 8 of the IC body 4b, while the other main surface of the adhesive film 23 is bonded to the bottom 11a of the recess 11 of the case 2, and thus the IC body 4b and the case 2 are bonded together through the adhesive film 23 to form the IC card 1e.

Also in this sixth embodiment it is possible to obtain substantially the same effects as in the first embodiment. In this embodiment, moreover, the IC card 1e is formed by bonding the IC body 4b (IC body 4) and the case 2 to each other with use of the adhesive film 23 which is not a liquid or gel- or paste-like adhesive but a filmy adhesive. Therefore, the material (bonding material) for bonding the IC body 4b to the case 2 can be prevented from overflowing to the outer surface side through a gap formed between a side wall of the recess 11 of the case 2 and a side face of the IC body 4b (IC body 4).

Of course, the contents of this sixth embodiment may be combined with the second embodiment, whereby it is possible to further improve the mounting stability of the IC body 4b (4) with respect to the case 2.

### SEVENTH EMBODIMENT

FIG. 55 is a perspective view of a case 2f used in manufacturing an IC card 1f according to a seventh embodiment of the present invention and FIG. 56 is a sectional view taken on line G-G of the case 2f of FIG. 55, corresponding substantially to FIGS. 13 and 15, respectively, in the first embodiment. FIGS. 57 to 59 are sectional views of the IC card 1f in manufacturing steps, showing sections of the same region as FIG. 56.

In the first embodiment the region near the recess 11 of the case 2 is deformed (plastically deformed) to temporarily fix the IC body 4 to the case 2 and thereafter the bonding material 3 is cured, but in this seventh embodiment a metallic cap portion 61 is provided in a case 2f (corresponding to the case 2) and is deformed to temporarily fix the IC body 4 to the case 2f, then the bonding material 3 is cured.

The following description is now provided about a manufacturing process for an IC card 1f according to this seventh embodiment.

Also in this embodiment, an IC body 4 is provided in the same way as in the first embodiment. Then, as shown in FIGS. 55 and 56, a case 2f used in fabricating the IC card 1f of this embodiment is provided. A manufacturing process for the case 2f may be performed before, after or simultaneously with the manufacturing process for the IC body 4.

The case 2f used in manufacturing the IC card 1f of this embodiment comprises a resin material portion 62 formed of a resin material and a metallic cap portion (metallic material portion) 61 formed of a metallic material. The resin material portion 62 can be formed using the same material (thermoplastic resin material) as that of the case 2 in the first embodiment. The metallic cap portion 61 and the resin material portion 62 are united to form the case 2f. The metallic cap portion 61 has a shape which permits the IC body 4 to be fitted (receive) therein.

The case 2f can be formed by various methods. For example, the case 2f as an integral combination of both metallic cap portion 61 and resin material portion 62 can be formed by providing a mold having a cavity of a shape conforming to the case 2f, disposing the metallic cap portion 61 into the mold cavity, then pouring a resin material (a thermoplastic resin material containing a filler) for forming the resin material portion 62 into the mold cavity and curing the resin material. The case 2f has a card-shaped outline which is almost the same as the outline of the case 2, but the metallic cap portion 61 has a recess (depression) 63 which permits the IC body 4 to be engaged (fitted) therein. The outline of the case 2f is substantially the same as that of the case 2, the recess in the metallic cap portion 61 of the case 2f corresponds to the recess 11 of the case 2, and a bottom 63a and a side wall (inner side wall) of the recess 63 in the metallic cap portion 61 of the case 2f correspond to the bottom 11a and the side wall 11b, respectively, of the recess 11 of the case 2.

After the case 2f and IC body 4 of such structures are provided, the bonding material 3 is disposed (applied) onto the bottom 63a of the recess 63 in the metallic cap portion 61 of the case 2f in the same manner as in the first embodiment, as shown in FIG. 57. Thereafter, as shown in FIG. 58, the IC body 4 is mounted (fitted) through the bonding material 3 into the recess 63 of the metallic cap portion 61 of the case 2f in such a manner that the surface 12a of the IC body 4 (upper surface of the sealing portion 8) is opposed to the bottom 63a of the recess 63 in the metallic cap portion 61 of the case 2f.

Next, in this embodiment, unlike the first embodiment, a part of the metallic cap portion 61 of the case 61 is deformed to fix (temporarily fix) the IC body 4 into the recess 63 of the metallic cap portion 61 of the case 2f, as shown in FIG. 59.

In the stage where the case 2f is formed, a part (pawl portion or projecting portion) 61b of the metallic cap portion 61 of the case 2f is kept projected from a back surface (lower surface or main surface) 62b of the resin material portion 62 of the case 2f, and after mounting the IC body 4 into the recess 63 of the metallic cap portion 61 of the case 2f through the bonding material 3, the part 61b of the metallic cap portion 61 is bent so as to extend onto the IC body 4. As a result, the IC body 4 is held and fixed by the part (i.e., bent part) 61b of the metallic cap portion 61 bent and extending onto the IC body 4. Since the part 61b of the metallic cap portion 61 projecting from the back surface 62b of the resin material portion 62 is bent, the back surface of the IC card 1f formed by both the back surface 62b of the resin material portion and the back surface 12b of the IC body 4 becomes nearly flat.

Thus, in a state in which the part 61b of the metallic cap portion 61 is deformed to fix (temporarily fix) the IC body 4 into the recess 63 of the metallic cap portion 61 of the case 2f, the bonding material 3 is cured as in the first embodiment, whereby there is formed an IC card 1f comprising the IC body 4 and the case 2f which are bonded and united through the bonding material 3. Therefore, in the IC card 1f fabricated, the part 61b of the metallic cap portion 61 of the case 2f is in an extended state.

In this embodiment, the case 2f is formed by the resin material portion 62 and the metallic cap portion 61 and the IC body 4 is bonded to the metallic cap portion 61 of the case 2f through the bonding material 3 to form the IC card 1f. Since the metallic cap portion 61 is made of a metallic material, the thermal conductivity thereof is higher and the time required for heating and cooling is shorter than those of the resin material, so that the time (curing time of the bonding material 3) required for the bonding material 3 to bond the IC body 4 to the metallic cap portion 61 can be shortened. Besides, since the IC body 4 is covered with the metallic cap portion 61, it is possible to shield the IC body 4 electromagnetically and hence possible to fabricate the IC card 1f high in electromagnetic shieldability. Further, it is possible to suppress or prevent the generation of radiation noise from the IC body 4 of the IC card 1f.

In this embodiment, after the IC body 4 is mounted into the recess 63 of the metallic cap portion 61 of the case 2f through the bonding material 3, the part 61b of the metallic cap portion 61 is deformed (bent) to fix (temporarily fix) the IC body 4 to the case 2f and in this state the bonding material 3 is cured. Therefore, it is possible to prevent movement of the IC body 4 from the case 2f during curing (before completion of curing) of the bonding material 3. Thus, the IC card 1f can be fabricated with high accuracy so that a final thickness thereof after curing of the bonding material 3 conforms to the standard value (target value). As a result, it is possible to improve the production yield of the IC card.

The shielding may be strengthened electrically by connecting the bent part 61b of the metallic cap portion 61 to a wiring portion (a terminal to which the ground supply voltage is applied) of a ground pattern on the wiring substrate 5 of the IC body 4. By so doing, it is possible to prevent an inconvenience caused by external static electricity for example.

For maximizing the thickness of the IC body 4 and maximizing the number of semiconductor chips 7 mounted, the bottom (the surface on the side opposite to the bottom 63a) side of the metallic cap portion 61 may be exposed without the resin material portion 62, whereby the depth of the recess 63 can be designed to a maximum.

The shape of the metallic cap portion 61 shown in this embodiment may be made such a shape as in the second and third embodiment, whereby it is possible to enhance the mounting stability of the IC body 4 with respect to the metallic cap 61 in the case 2f and improve the production yield of the IC card.

The contents of this embodiment may be combined with the fourth embodiment, whereby the production yield of the IC card can be further improved.

### EIGHTH EMBODIMENT

FIGS. 60 and 61 are sectional views in manufacturing steps of an IC card 1g according to an eighth embodiment of the present invention, showing sections of the same region as FIGS. 57 to 59 in the seventh embodiment.

In the previous seventh embodiment the IC body 4 is bonded to the metallic cap portion 61 of the case 2f through the bonding material 3 to form the IC card 1f, but in this eighth embodiment an IC body 4b is bonded to the metallic cap 61 of the case 2f though an adhesive film 23 to form the IC card 1g.

The following description is now provided about a manufacturing process for the IC card 1g of this embodiment.

First, an IC body 4b is provided in the same way as in the sixth embodiment and a case 2f is provided in the same way as in the seventh embodiment.

Next, as shown in FIG. 60, the IC body 4b is mounted (fitted) into the recess 63 of the metallic cap portion 61 of the case 2f. In this case, it is not necessary to dispose (apply) the bonding material 3 onto the bottom 63a of the recess 63 in the metallic cap portion 61 of the case 2f. The IC body 4b is mounted into the recess 63 of the metallic cap portion 61 of the case 2f in such a manner that the adhesive film 23 of the IC body 4b comes into opposed contact with the bottom 63a of the recess 63.

Then, in the same manner as in the seventh embodiment, as shown in FIG. 61, the part 61b of the metallic cap portion 61 of the case 2f is deformed (bent) to fix (temporarily fix) the IC body 4b into the recess 63 of the metallic cap portion 61 of the case 2f.

The adhesive film 23 is cured in a state in which the part 61b of the metallic cap portion 61 is thus deformed to fix (temporarily fix) the IC body 4b into the recess 63 in the metallic cap portion 61 of the case 2f, whereby there is formed an IC card 1g comprising the IC body 4b (IC body 4) and the case 2f which are bonded and united through the adhesive film 23.

According to this eighth embodiment it is possible to obtain substantially the same effects as in the seventh embodiment. In this embodiment, moreover, the IC card 1g is formed by bonding the IC body 4b and the metallic cap portion 61 of the case 2f with each other through the adhesive film 23, so that the material (bonding material) for bonding the IC body 4b to the metallic cap portion 61 of the case 2f can be prevented from overflow to the outer surface side through the gap between the metallic cap portion 61 and the IC body 4b. Consequently, it is possible to further improve the production yield of the IC card.

Further, the shielding may be strengthened electrically by connecting the bent part 61b of the metallic cap portion 61 to a wiring portion (a terminal to which the ground supply voltage is applied) of a ground pattern on the wiring substrate 5 of the IC body 4b. By so doing, it is possible to prevent the occurrence of an inconvenience caused by external static electricity for example.

### NINTH EMBODIMENT

FIGS. 62 and 63 are sectional views in manufacturing steps of an IC card 1h according to a ninth embodiment of the present invention, showing sections of the same region as FIGS. 57 to 59 in the seventh embodiment.

In the seventh embodiment the bonding material 3 is cured after fixing the IC body temporarily to the metallic cap portion 61 of the case 2f, but in this ninth embodiment the IC body 4 is fixed temporarily to the metallic cap portion 61 of the case 2f without using the bonding material.

A description will be given below about a manufacturing process for the IC card 1h according to this embodiment.

First, an IC body 4 is provided in the same way as in the first embodiment and a case 2f is provided in the same way as in the seventh embodiment.

Next, as shown in FIG. 62, the IC body 4 is mounted (fitted) into the recess 63 of the metallic cap portion 61 of the case 2f. In this case, the bonding material is not disposed (applied) onto the bottom 63a of the recess 63 in the metallic cap portion 61 of the case 2f, but the IC body 4 is mounted into the recess 63 of the metallic cap portion 61 in such a manner that the surface 12a thereof (upper surface of the sealing portion 8) comes into opposed contact with the bottom 63a of the recess 63a in the metallic cap portion 61 of the case 2f.

Then, in the same way as in the seventh embodiment, as shown in FIG. 63, the part 61b of the metallic cap portion 61 of the case 2f is deformed (bent) to fix the IC body 4 into the recess 63 of the metallic cap portion 61. In this case, the part (pawl portion or projecting portion) 61b of the metallic cap portion 61 of the case 2f is kept projected from the back surface 62b of the resin material portion 62 of the case 2f in the stage where the case 2f is formed, and after mounting the IC body 4 into the recess 63 of the metallic cap portion 61 of the case 2f, the part 61b of the metallic cap portion 61 is bent. As a result, the part 61b of the metallic cap portion 61 extends onto the IC body 4 and holds down the IC body 4 firmly. Moreover, since the part 61b of the metallic cap portion 61 projecting from the back surface 62b of the resin material portion 62 is bent, the back surface of the IC card 1h formed by both the back surface 62b of the resin material portion 62 and the back surface 12b of the IC body 4 becomes nearly flat.

By thus deforming the part 61b of the metallic cap portion 61 of the case 2f to fix the IC body 4 into the recess 63 of the metallic cap portion 61, there is formed an IC card 1h comprising the IC body 4 and the case 2f which are united together.

In this embodiment, since the IC body 4 is covered with the metallic cap portion 61, the IC body 4 can be shielded electromagnetically and it is possible to obtain an IC card 1h high in electromagnetic shieldability. Besides, it is possible to suppress or prevent the generation of radiation noise from the IC body 4 of the IC card 1h.

In this embodiment, moreover, after mounting the IC body 4 into the recess 63 of the metallic cap portion 61 of the case 2f, the part 61b of the metallic cap portion 61 is deformed (bent) to fix the IC body 4 to the case 2f, thereby fabricating the IC card 1h. Since it is not necessary to use a bonding material for fixing the IC body 4 to the case 2f, the IC card manufacturing process can be simplified. Besides, since the bonding material thickness can be omitted, it is possible to make the IC card thinner and improve the production yield of the IC card. Additionally, the IC card manufacturing cost can be reduced.

Further, the shielding may be strengthened by connecting the bent part 61b of the metallic cap portion 61 to a wiring portion (a terminal to which the ground supply voltage is applied) of a ground pattern on the wiring substrate 5 of the IC body 4. By so doing, it is possible to prevent the occurrence of an inconvenience caused by external static electricity for example.

### TENTH EMBODIMENT

FIG. 64 is a back view (bottom view, underside view or plan view) of a case 2k used in manufacturing an IC card 1k according to a tenth embodiment of the present invention and FIG. 65 is a sectional view taken on line H-H of the case 2k of FIG. 64, corresponding to FIGS. 14 and 15, respectively, in the first embodiment. FIGS. 66 and 67 are sectional views of the IC card 1k of this embodiment in manufacturing steps, showing sections of the same region as FIG. 65.

In the first embodiment a region near the recess 11 of the case 2 is deformed (plastically deformed) to fix the IC body 4 temporarily to the case 2 and then the bonding material 3 is cured, but in this tenth embodiment the IC body 4 is fixed temporarily to the case 2k by virtue of elasticity of the case 2k (corresponding to the case 2) and then the bonding material 3 is cured.

A manufacturing process for the IC card 1k of the preferred embodiment will be described.

Also in this embodiment an IC body 4 is provided as in the first embodiment. Then, as shown in FIGS. 64 and 65, a case 2k used in manufacturing the IC card 1k of this embodiment is provided. A manufacturing process for the case 2k may be performed before, after or simultaneously with the manufacturing process for the IC body 4.

The case 2k, like the case 2 in the first embodiment, has a recess 11 which permits the IC body 4 to be fitted therein, but unlike the case 2 the case 2k is further provided with protuberances (lugs, lug-like portions or protruding portions) 71 on side walls (side faces) 11b of the recess 11. In the recess 11 of the case 2k, as shown in FIGS. 64 and 65, it is preferable that the protuberances 71 be formed on both side walls in the longitudinal direction of the case 2k. Except that the protuberances 71 are formed on the side walls 11b of the recess 11, the case 1k has almost the same structure as the case 2 in the first embodiment and is formed using the same material as that of the case 2.

The case 2k can be manufactured by a method which is substantially the same as the manufacturing method for the case 2 in the first embodiment. For example, the case 2k can be fabricated by an injection molding method using a mold which has a cavity of a shape substantially conforming to the shape of the case 2k. Since the protuberances 71 are provided on the side walls 11b of the recess 11 of the case 2k, it is preferable for the mold to be provided with a movable portion so that a part of the mold is moved at the time of mold release. This is preferred because the mold release can be done smoothly.

After the case 2k and IC body 4 of such structures are provided, the bonding material 3 is disposed (applied) onto the bottom 11a of the recess 11 of the case 2k in the same way as in the first embodiment, as shown in FIG. 66. Then, as shown in FIG. 67, the IC body 4 is mounted (fitted) into the recess 11 of the case 2k through the bonding material 3 in the same way as in the first embodiment.

Since the protuberances 71 are formed on the side walls 11b of the recess 11 of the case 2k as described above, once the IC body 4 is fitted into the recess 11 of the case 2k, side faces of the IC body 4 are pressed against the side walls 11b of the recess 11 by the protuberances 71 and the IC body 4 is fixed (temporarily fixed). That is, when the IC body 4 is mounted into the recess 11 of the case 2k through the bonding material 3, the IC body 4 is fixed to the side walls 11b of the recess 11 by the protuberances 71. If the case 2k is formed using a thermoplastic resin, the case 2k becomes somewhat elastic and this advantageous for the protuberances 71 to press and fix the side faces of the IC body 4 against the side walls 11b of the recess 11. In this embodiment, therefore, it is not necessary to let the case 2k be deformed elastically by the tool 21 as in the first embodiment.

Thus, with the IC body 4 fixed (temporarily fixed) to the recess 11 of the case 2k, the bonding material 3 is cured as in the first embodiment, whereby there is formed an IC card 1k comprising the IC body 4 and the case 2k which are bonded and united through the bonding material 3.

In this embodiment, the IC body 4 is mounted into the recess 11 of the case 2k through the bonding material 3 and is fixed (temporarily fixed) to the case 2k by the protuberances 71 formed on the side walls 11b of the recess 11, then in this state the bonding material 3 is cured. Therefore, it is possible to prevent movement of the IC body 4 from the case 2k during curing (before complete curing) of the bonding material 3. Consequently, the IC card 1k can be fabricated with high accuracy so that a final thickness thereof conforms to the standard value (target value). As a result, it is possible to improve the production yield of the IC card.

If the height h₁ of each of the protuberances 71 formed on the side walls 11b of the recess 11 of the case 2k is too large, the case 2k may warp when the IC body 4 is fitted into the recess 11 of the case. However, if the height h1 of each of the protuberances 71 is set at about 10 to 100 μm, it becomes possible to fix (temporarily fix) the IC body 4 into the recess 11 of the case 2k while suppressing or preventing the warp of the case 2k.

### ELEVENTH EMBODIMENT

FIGS. 68 and 69 are sectional views in manufacturing steps of an IC card 1m according to an eleventh embodiment of the present invention, showing sections of the same region as FIGS. 58 and 59 in the seventh embodiment.

In the seventh embodiment the metallic cap portion 6 is fitted into the groove (recess) formed in the case 2f (the resin material portion 62 thereof), but in this eleventh embodiment the groove is formed through the case 2f (the resin material portion 62 thereof) and the metallic cap portion 61 is exposed to the main surface 13a side of the case 2f. According to this structure, the thickness of the case 2f (the resin material portion 62 thereof) at the bottom of the metallic cap 61 can be omitted in comparison with the seventh embodiment, whereby the IC card 1m can be made thinner. Alternatively, for effective utilization of the thickness corresponding to the omitted thickness, for example a semiconductor chip such as a flash memory chip can be stacked on the semiconductor chip 7, thus making it possible to attain a large capacity of the IC card 1m. In the illustrated example, a semiconductor chip 7 is further stacked on the semiconductor chip 7.

As shown in FIG. 69, in this embodiment, like the seventh embodiment, the IC body 4 is mounted into the recess 63 of the metallic cap portion 61 of the case 2f and thereafter the part 61b of the metallic cap portion 61 is deformed (bent), whereby the IC body 4 is fixed to the case 2f to fabricate the IC card 1m.

In this eleventh embodiment, recesses 81 for fitting therein of the metallic cap portion 61 are formed in side walls within the groove of the resin material portion 62 of the case 2f. On the other hand, protuberances 82 are formed in the metallic cap portion 61 to match the shape of the recesses 81. By fitting the protuberances 82 into the recesses 81, the metallic cap portion 61 can be fixed stably to the case 2f (the resin material portion 62 thereof). of course, the metallic cap portion 61 can be fixed more stably by providing plural such recesses 81 and protuberances 82.

Thus, since the bonding material for fixing the IC body 4 to the case 2f becomes unnecessary, the IC card manufacturing process can be simplified. Moreover, since the thickness of the bonding material can be omitted, the IC card can be made thinner and it is possible to improve the production yield of the IC card. It is also possible to reduce the IC card manufacturing cost.

In this embodiment, since the IC body 4 is covered with the metallic cap portion 61, it is possible to shield the IC body 4 electromagnetically and hence possible to obtain an IC card 1m high in electromagnetic shieldability. Additionally, it is possible to suppress or prevent the generation of radiation noise from the IC body 4 of the IC card 1m.

The shielding may be strengthened electrically by connecting the bent portion 61b of the metallic cap portion 61 to a wiring portion (a terminal to which the ground supply voltage is applied) of a ground pattern on the wiring substrate 5 of the IC body 4. By so doing, it is possible to prevent the occurrence of an inconvenience caused by external static electricity for example.

Of course, the recesses 81 and protuberances 82 described in this embodiment are applicable to the seventh to ninth embodiments, whereby it is possible to obtain the same effects as in those embodiments.

Although the present invention has been described above concretely by way of embodiments thereof, it goes without saying that the present invention is not limited to the above embodiments, but that various changes may be made within the scope not departing from the gist of the invention.

For example, the adhesive film is not always required to be curable thermally or reactively, but the curing treatment may be omitted if the desired bonding strength is achieved.

The present invention is applicable not only to memory cards incorporating flash memory (EEPROM) such as memory stick, MMC (multi-media card) and SD card but also to memory cards incorporating memory circuits such as SRAM (Static Random Access Memory), FRAM (Ferroelectric Random Access Memory) and MRAM (Magnetic Random Access Memory), as well as IC (Integrated Circuit) cards not having a memory circuit.

The present invention is suitable for application to, for example, such IC cards as semiconductor memory cards and a technique for manufacturing the same.

1. A method for manufacturing an IC card, comprising the steps of:
(a) providing a semiconductor device, the semiconductor device having a wiring substrate and a semiconductor chip mounted over the wiring substrate and further having over a first surface thereof external connecting terminals connected electrically to the semiconductor chip;
(b) providing a case which permits the semiconductor device to be mounted thereon;
(c) mounting the semiconductor device onto the case through a bonding material;
(d) after the step (c), deforming a part of the case to fix the semiconductor device to the case; and
(e) curing the bonding material to bond the semiconductor device to the case through the bonding material.

2. The method according to 1, wherein the step (d) is carried out before curing of the bonding material in the step (e).

3. The method according to 1,
wherein the case provided in the step (b) is formed using a resin material, and
wherein, in the step (d), the case is deformed plastically to fix the semiconductor device to the case.

4. The method according to 3, wherein the case provided in the step (b) is formed using a thermoplastic resin material.

5. The method according to 1,
wherein the case provided in the step (b) has a recess which permits the semiconductor device to be mounted therein,
wherein, in the step (c), the semiconductor device is mounted into the recess of the case through the bonding material in such a manner that the first surface is an outer surface, and
wherein, in the step (d), a region near the recess of the case is deformed.

6. The method according to 5,
wherein the semiconductor device provided in the step (a) has the wiring substrate, the semiconductor chip, and a sealing portion for sealing the semiconductor chip,
the sealing portion being formed of a thermosetting resin material.

7. The method according to 5, wherein a protuberance is formed over a bottom of the recess of the case or over a second surface of the semiconductor device, the second surface being located on the side opposite to the first surface.

8. The method according to 5, wherein the step (c) comprises the steps of:
(c1) disposing the bonding material to a bottom of the recess of the case; and
(c2) after the step (c1), mounting the semiconductor device into the recess of the case to which the bonding material is disposed.

9. The method according to 5, wherein the bonding material is an adhesive film affixed to the semiconductor device provided in the step (a).

10. The method according to 1,
wherein the case provided in the step (b) has a first portion formed of a resin material and a second portion formed of a metallic material and permitting the semiconductor device to be mounted thereon, and
wherein, in the step (c), the semiconductor device is mounted over the second portion of the case.

11. The method according to 10, wherein in the step (d) a part of the second portion of the case is bent to fix the semiconductor device to the case.

12. A method for manufacturing an IC card, comprising the steps of:
(a) providing a semiconductor device, the semiconductor device having a wiring substrate and a semiconductor chip mounted over the wiring substrate and further having on a first surface thereof external connecting terminals connected electrically to the semiconductor chip;
(b) providing a case formed of a resin material, the case having a recess which permits the semiconductor device to be mounted therein;
(c) mounting the semiconductor device into the recess of the case through a bonding material in such a manner that the first surface is an outer surface; and
(d) curing the bonding material to bond the semiconductor device to the case through the bonding material,
wherein a protuberance is formed over a bottom of the recess of the case provided in the step (b) or over a second surface of the semiconductor device provided in the step (a), the second surface being located on the side opposite to the first surface.

13. The method according to 12, wherein the step (c) comprises the steps of:
(c1) disposing the bonding material to a bottom of the recess of the case; and
(c2) after the step (c1), mounting the semiconductor device into the recess of the case to which the bonding material is disposed.

14. The method according to 13, wherein the bonding material disposed to the bottom of the recess of the case in the step (c1) is a liquid or gel- or paste-like bonding material.

15. The method according to 12, wherein another recess is formed in an end portion of the bottom of the recess of the case.

16. The method according to 12, wherein the semiconductor device provided in the step (a) has the wiring substrate, the semiconductor chip, and a sealing portion for sealing the semiconductor chip, and
wherein the second surface is a surface of the sealing portion.

17. A method for manufacturing an IC card, comprising the steps of:
(a) providing a semiconductor device, the semiconductor device having a wiring substrate and a semiconductor chip mounted over the wiring substrate and further having over a first surface thereof external connecting terminals connected electrically to the semiconductor chip;
(b) providing a case having a first portion formed of a resin material and a second portion formed of a metallic material, the second portion permitting the semiconductor device to be mounted thereover, the first and second portions being in a united state;
(c) mounting the semiconductor device over the second portion of the case; and
(d) after the step (c), deforming a part of the second portion to fix the semiconductor device to the case.

18. A method for manufacturing an IC card, comprising the steps of:
(a) providing a semiconductor device, the semiconductor device having a wiring substrate and a semiconductor chip mounted over the wiring substrate and further having over a first surface thereof external connecting terminals connected electrically to the semiconductor chip;
(b) providing a case formed of a resin material, the case having a recess which permits the semiconductor device to be mounted therein;
(c) mounting the semiconductor device into the recess of the case through a bonding material; and
(d) curing the bonding material to bond the semiconductor device to the case through the bonding material,
wherein a protuberance is formed over a side wall of the recess of the case, and
wherein when the semiconductor device is mounted into the recess of the case in the step (c), the semiconductor device is fixed by the protuberance formed over the side wall of the recess of the case.

19-22. (canceled)
